(19) United States
(12) Patent Application Publication
(10) Pub. No.: US 2026/0107377 A1
(43) Pub. Date: Apr. 16, 2026

(54) ELECTRONIC DEVICE

(71) Applicant: ROHM CO., LTD., Kyoto-shi, Kyoto (JP)

(72) Inventor: Hiroki MIYAZAKI, Kyoto-shi, Kyoto (JP)

(21) Appl. No.: 19/421,925

(22) Filed: Dec. 16, 2025

Related U.S. Application Data
(63) Continuation of application No. PCT/JP2024/019376, filed on May 27, 2024.

(30) Foreign Application Priority Data
Jun. 21, 2023 (JP) 2023-101351

(51) Int. Cl. H05K 1/02; H05K 1/181; H05K 3/28

(52) U.S. Cl. CPC H05K 1/0296; H05K 1/181; H05K 3/284

(57) ABSTRACT

An electronic device includes: a plurality of electronic components, each including a pair of terminals; a support member including a support surface that supports the plurality of electronic components; a wiring layer formed on the support surface; and a sealing resin covering each of the plurality of electronic components. The wiring layer includes a first wiring section to which one of the pair of terminals of each of the plurality of electronic components is bonded. Electrical characteristics of the plurality of electronic components are equivalently represented by a single circuit symbol in a circuit diagram.

### TECHNICAL FIELD

The present disclosure relates to an electronic device

### BACKGROUND ART

An electronic device provided with a plurality of electronic components has been conventionally known. JP-A-2021-34600 discloses an example of a conventional electronic device. The electronic device (semiconductor device) disclosed in JP-A-2021-34600 includes an insulating layer, a wiring layer, a plurality of bonding layers, a plurality of electronic components, and a sealing resin. The wiring layer is disposed on the insulating layer. Each of the electronic components is a passive element such as a resistor, a capacitor, or an inductor, or a diode. The electronic components are of a surface-mountable chip type. The electronic components are bonded to the wiring layer via the bonding layers. The sealing resin is formed on the insulating layer to cover the wiring layer, the bonding layers, and the electronic components.

### BRIEF DESCRIPTION OF THE DRAWINGS

FIG. 1 is a perspective view showing an electronic device according to a first embodiment as seen from a bottom surface side.

FIG. 2 is a plan view showing the electronic device according to the first embodiment, with a sealing resin indicated by imaginary lines.

FIG. 3 is a partially enlarged view showing a part of FIG. 2.

FIG. 4 corresponds to the plan view of FIG. 2, but omits the sealing resin and indicates a semiconductor element and a plurality of electronic components with imaginary lines.

FIG. 5 is a bottom view showing a semiconductor device according to the first embodiment.

FIG. 6 is a cross-sectional view along line VI-VI in FIG. 2.

FIG. 7 is a partially enlarged view showing a part of FIG. 6.

FIG. 8 is a cross-sectional view along line VIII-VIII in FIG. 2.

FIG. 9 is a cross-sectional view along line IX-IX in FIG. 2.

FIG. 10 is a partially enlarged view showing a part of FIG. 9.

FIG. 11 is a circuit diagram showing a part (two first electronic components and two second electronic components) of the electronic device according to the first embodiment.

FIG. 12 is a circuit diagram that equivalently represents the circuit configuration shown in FIG. 11.

FIG. 13 is a cross-sectional view showing a step of a method for manufacturing the electronic device according to the first embodiment.

FIG. 14 is a cross-sectional view showing a step of the method for manufacturing the electronic device according to the first embodiment.

FIG. 15 is a cross-sectional view showing a step of the method for manufacturing the electronic device according to the first embodiment.

FIG. 16 is a cross-sectional view showing a step of the method for manufacturing the electronic device according to the first embodiment.

FIG. 17 is a cross-sectional view showing a step of the method for manufacturing the electronic device according to the first embodiment.

FIG. 18 is a cross-sectional view showing a step of the method for manufacturing the electronic device according to the first embodiment.

FIG. 19 is a cross-sectional view showing a step of the method for manufacturing the electronic device according to the first embodiment.

FIG. 20 is a cross-sectional view showing a step of the method for manufacturing the electronic device according to the first embodiment.

FIG. 21 is a cross-sectional view showing a step of the method for manufacturing the electronic device according to the first embodiment.

FIG. 22 is a cross-sectional view showing a step of the method for manufacturing the electronic device according to the first embodiment.

FIG. 23 is a cross-sectional view showing a step of the method for manufacturing the electronic device according to the first embodiment.

FIG. 24 is a partially enlarged plan view showing an electronic device according to a first variation of the first embodiment, and corresponds to FIG. 3.

FIG. 25 is a cross-sectional view showing an electronic device according to a second variation of the first embodiment, and corresponds to the cross section in FIG. 6.

FIG. 26 is a schematic view showing an electronic device according to a third variation of the first embodiment.

FIG. 27 is a partially enlarged plan view showing an electronic device according to a second embodiment, and corresponds to FIG. 3.

FIG. 28 is a cross-sectional view showing the electronic device according to the second embodiment, and corresponds to the cross section in FIG. 6.

FIG. 29 is a partially enlarged cross-sectional view of FIG. 28, showing the electronic device according to the second embodiment.

FIG. 30 is a partially enlarged plan view showing an electronic device according to a variation of the second embodiment, and corresponds to FIG. 3.

FIG. 31 is a partially enlarged cross-sectional view showing the electronic device according to the variation of the second embodiment, and corresponds to the cross section in FIG. 10.

FIG. 32 is a partially enlarged plan view showing an electronic device according to a third embodiment, and corresponds to FIG. 3.

FIG. 33 is a partially enlarged cross-sectional view showing the electronic device according to the third embodiment, and corresponds to the cross section in FIG. 10.

FIG. 34 is a schematic view showing an electronic device according to another embodiment.

FIG. 35 is a cross-sectional view showing an electronic device according to another embodiment, and corresponds to the cross section in FIG. 6.

### DETAILED DESCRIPTION OF EMBODIMENTS

The following describes preferred embodiments of an electronic device according to the present disclosure with reference to the drawings. In the following description, identical or similar elements are denoted by the same reference numerals and redundant descriptions of such elements are omitted. The terms such as "first", "second" and "third" in the present disclosure are used merely as labels and not intended to impose orders on the elements accompanied with these terms.

In the present disclosure, the phrases "an object A is formed in an object B" and "an object A is formed on an object B" include, unless otherwise specified, "an object A is formed directly in/on an object B" and "an object A is formed in/on an object B with another object interposed between the object A and the object B". Similarly, the phrases "an object A is disposed in an object B" and "an object A is disposed on an object B" include, unless otherwise specified, "an object A is disposed directly in/on an object B" and "an object A is disposed in/on an object B with another object interposed between the object A and the object B". Similarly, the phrase "an object A is located on an object B" includes, unless otherwise specified, "an object A is located on an object B in contact with the object B" and "an object A is located on an object B with another object interposed between the object A and the object B". Further, the phrase "an object A overlaps with an object B as viewed in a certain direction" includes, unless otherwise specified, "an object A overlaps with the entirety of an object B" and "an object A overlaps with a portion of an object B". The phrase "an object A (or the material thereof) contains a material C" includes "an object A (or the material thereof) is made of a material C" and "an object A (or the material thereof) is mainly composed of a material C". Further, the phrase "a surface A faces (a first side or a second side) in a direction B", unless otherwise specified, is not limited to the case where the angle of the surface A with respect to the direction B is 90°, but also includes the case where the surface A is inclined to the direction B. The phrase "a surface A is perpendicular to a surface B" is not limited to the case where the angle of the surface A with respect to the surface B is exactly 90°, but also includes the case where the surface A is substantially perpendicular to the surface B.

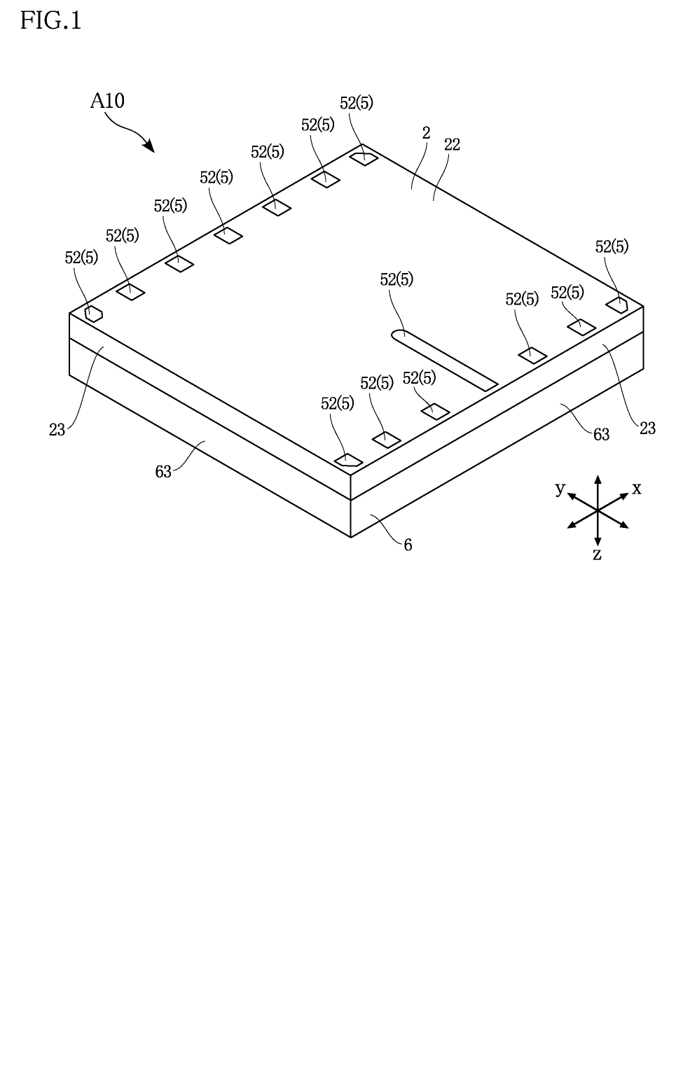

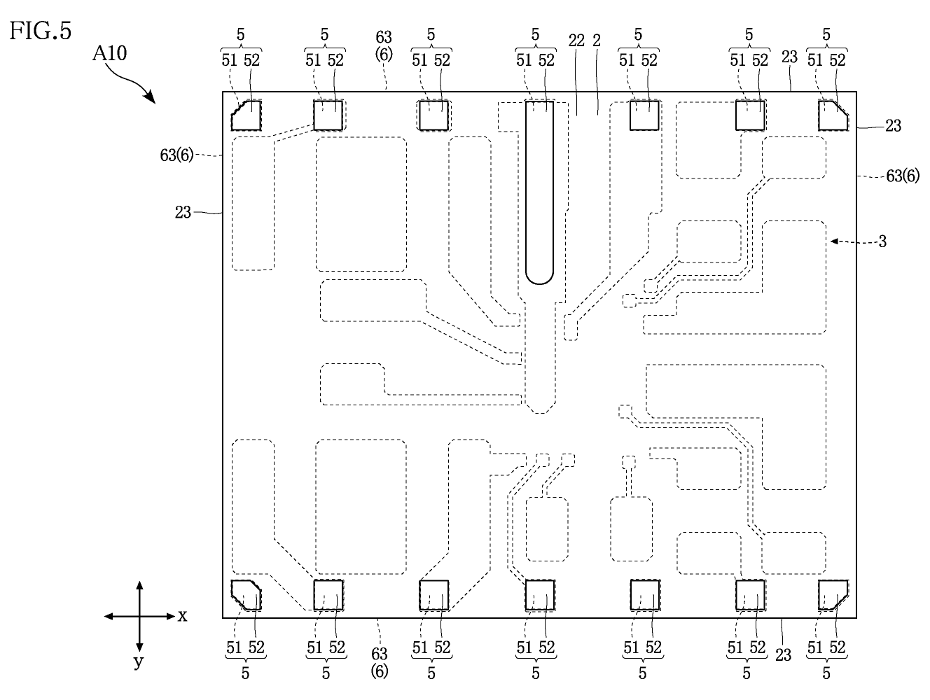

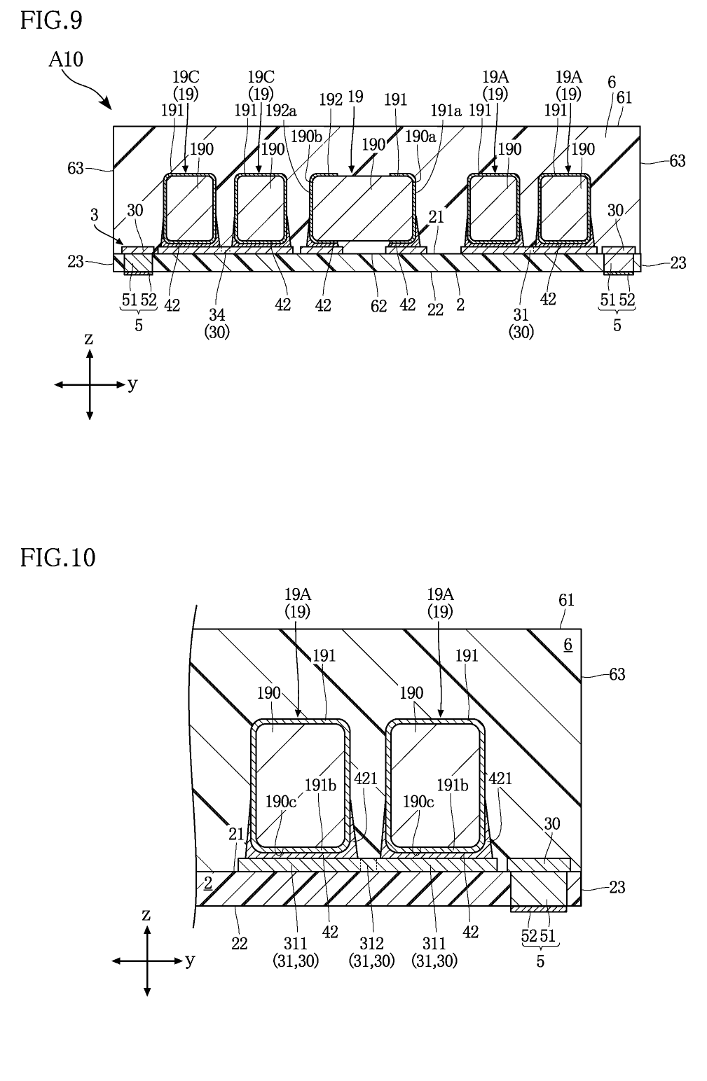

FIGS. 1 to 10 show an electronic device A10 according to a first embodiment. The electronic device A10 includes a semiconductor element 1, a plurality of electronic components 19, a support member 2, a wiring layer 3, a plurality of conductive bonding members 41 and 42, a plurality of outer terminals 5, and a sealing resin 6.

For convenience, reference will be made to a thickness direction z, a first direction x, and a second direction y that are perpendicular to each other. For example, the thickness direction z corresponds to the thickness direction of the electronic device A10. In the description below, a first side in the thickness direction z may be referred to as "upward", and a second side as "downward". The terms such as "top", "bottom", "upward", "downward", "upper surface", and "lower surface" are used to indicate the relative positions of elements and components in the thickness direction z and do not necessarily define the relationship with respect to the direction of gravity. In addition, "plan view" refers to the view seen in the thickness direction z.

The electronic device A10 is surface-mountable onto the wiring board of an electronic apparatus or an electric vehicle, for example. The electronic device A10 is of a leadless package type, specifically a quad flat non-leaded (QFN) package type. The electronic device A10 has a rectangular shape in plan view.

The semiconductor element 1 is a component that forms the functional core of the electronic device A10. The semiconductor element 1 is an integrated circuit such as an LSI. Unlike this example, the semiconductor element 1 may be a voltage control element such as a low drop out regulator (LDO), an amplification element such as an operational amplifier, or a discrete element such as a transistor or a diode. The semiconductor element 1 has a rectangular shape in plan view. The semiconductor element 1 is supported by the support member 2. The semiconductor element 1 overlaps with the support member 2 in plan view.

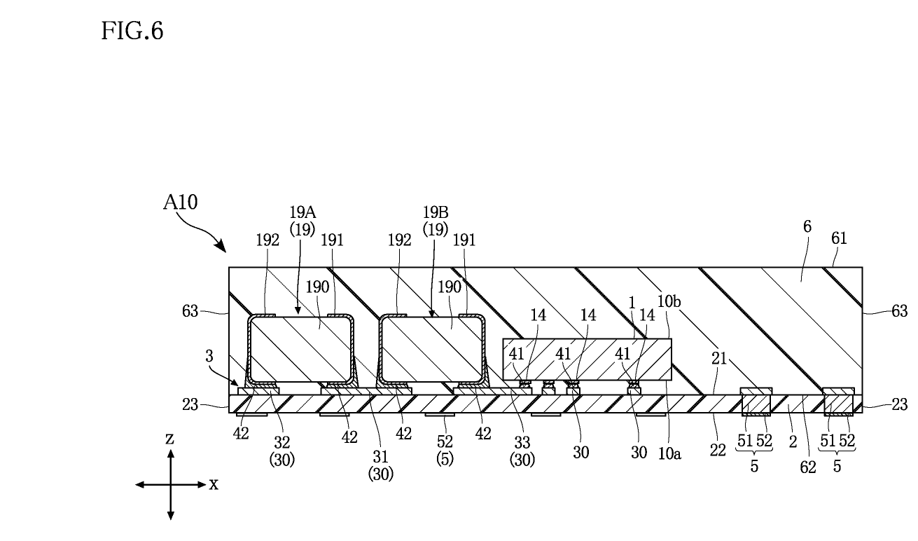

As shown in FIGS. 6 and 8, the semiconductor element 1 has an element obverse surface 10a and an element reverse surface 10b. The element obverse surface 10a and the element reverse surface 10b are spaced apart from each other in the thickness direction z. The element obverse surface 10a and the element reverse surface 10b face away from each other. The element obverse surface 10a faces the support member 2.

As shown in FIGS. 6 and 8, the semiconductor element 1 has a plurality of electrode pads 14. The electrode pads 14 are disposed on the element obverse surface 10a. The electrode pads 14 are electrically connected to an internal circuit (not illustrated) of the semiconductor element 1. Each of the electrode pads 14 is bonded to the wiring layer 3 via one of the conductive bonding members 41. With this configuration, the semiconductor element 1 is bonded to the wiring layer 3 with the surface (i.e., the element obverse surface 10a) on which the electrode pads 14 are disposed facing downward in the thickness direction z. In other words, the semiconductor element 1 is flip-chip mounted.

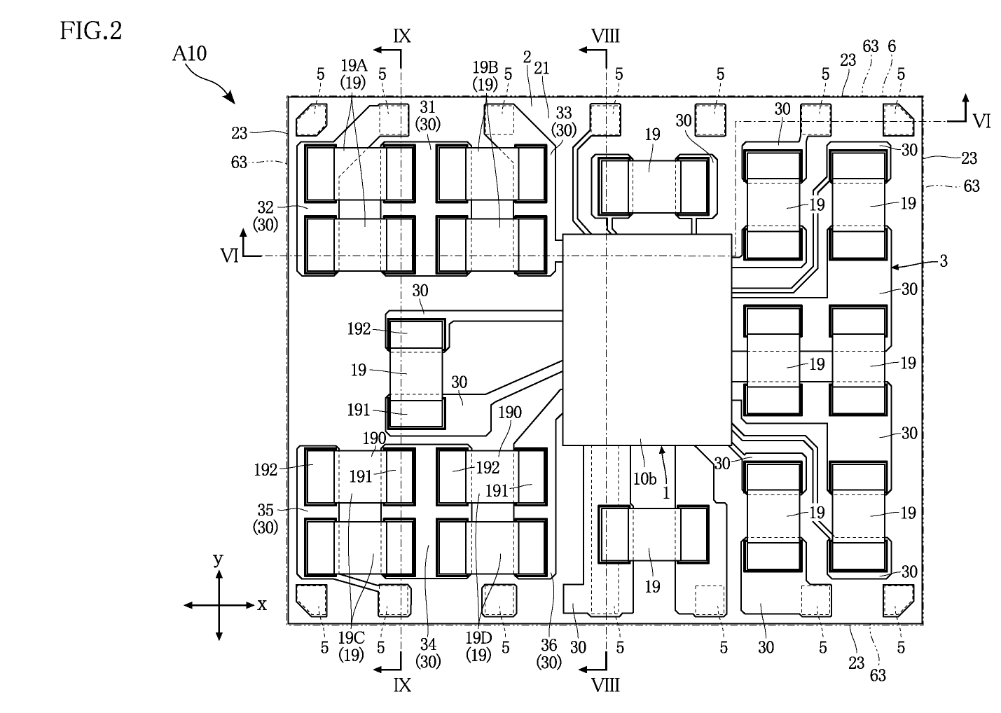

As shown in FIGS. 2, 6, 8, and 9, the electronic components 19 are supported by the support member 2. The electronic components 19 are surface-mount devices (SMD). Each of the electronic components 19 may be one of a resistor, a capacitor, or an inductor. The electronic components 19, as well as the semiconductor element 1, are the functional elements of the electronic device A10. The electronic components 19 are arranged around the semiconductor element 1 in plan view.

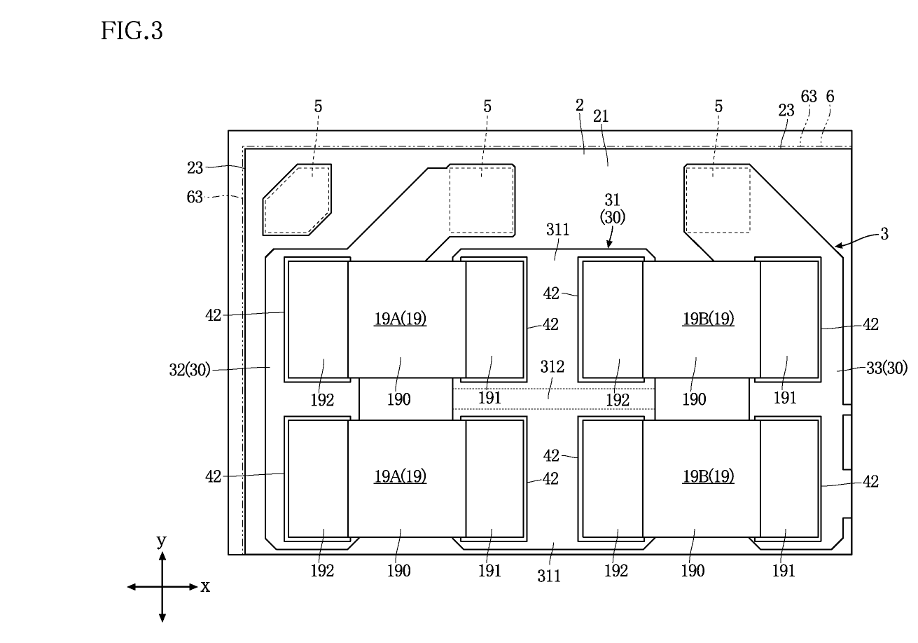

As shown in FIGS. 2 and 3, the electronic components 19 include at least one first electronic component 19A and at least one second electronic component 19B. In the illustrated example, the electronic components 19 include two first electronic components 19A and two second electronic components 19B. As will be understood from the configuration described in detail below, the two first electronic components 19A are electrically connected to each other in parallel. The two second electronic components 19B are electrically connected to each other in parallel. The two first electronic components 19A are electrically connected to the two second electronic components 19B in series.

In the present embodiment, each of the two first electronic components 19A and the two second electronic components 19B exhibits the same performance with respect to an electrical characteristic. The electrical characteristic is a resistance value when the electronic components 19 are resistors, a capacitance when the electronic components 19 are capacitors, and an inductance value when the electronic components 19 are inductors. In other words, in the electronic device A10, when the two first electronic components 19A and the two second electronic components 19B are resistors, their resistance values are the same (or substantially the same); when these electronic components are capacitors, their capacitances are the same (or substantially the same); when these electronic components are inductors, their inductance values are the same (or substantially the same). In a configuration different from that of the electronic device A10, each of the two first electronic components 19A and the two second electronic components 19B may exhibit different performance with respect to an electrical characteristic.

As shown in FIG. 2, the electronic components 19 include a plurality of electronic components 19C and 19D, and in the illustrated example, include two electronic components 19C and two electronic components 19D. As will be understood from the configuration described below, the two electronic components 19C are electrically connected to each other in parallel. The two electronic components 19D are electrically connected to each other in parallel. The two electronic components 19C are electrically connected to the two electronic components 19D in series.

In the present embodiment, each of the two electronic components 19C and the two electronic components 19D exhibits the same performance with respect to an electrical characteristic. In a configuration different from that of the electronic device A10, each of the two electronic components 19C and the two electronic components 19D may exhibit different performance with respect to an electrical characteristic.

As shown in FIGS. 2, 3, 6, 7, and 9, each of the electronic components 19 (including the first electronic components 19A, the second electronic components 19B, the electronic components 19C, and the electronic components 19D) includes a body 190 and a pair of terminals 191 and 192. Unless otherwise specified, the following description of the body 190 and the pair of terminals 191 and 192 applies to each of the electronic components 19 (including the first electronic components 19A, the second electronic components 19B, the electronic components 19C, and the electronic components 19D).

The body 190 forms the functional core of an electronic component 19, and operates as a resistor, a capacitor, or an inductor by energization of the electronic component 19. As shown in FIG. 3, the body 190 has a rectangular shape in plan view.

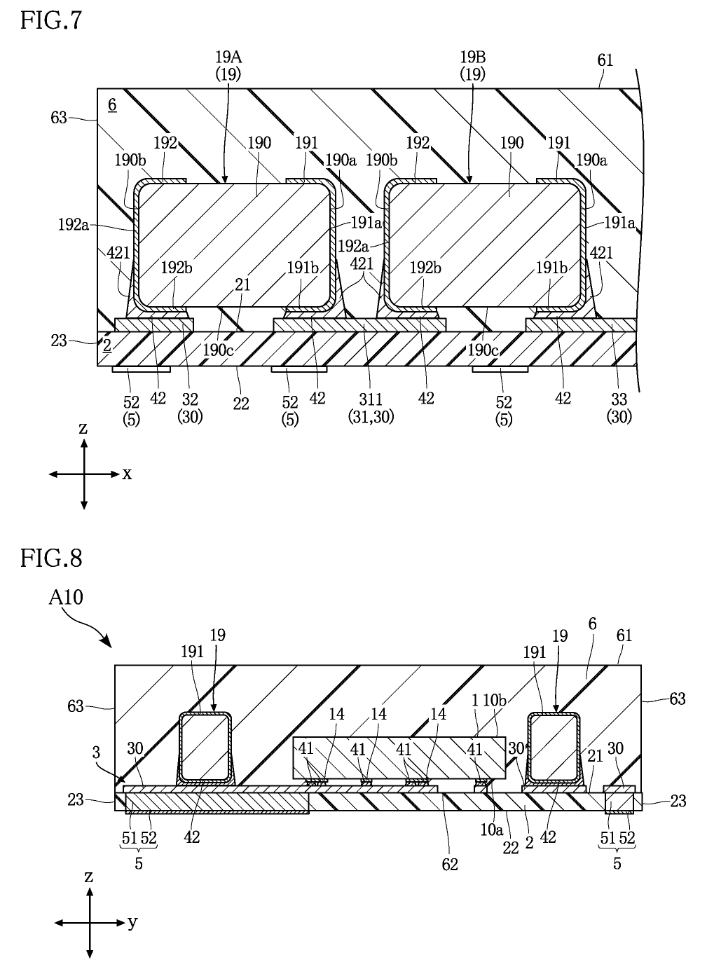

As shown in FIGS. 7 and 8, the body 190 has a pair of side surfaces 190a and 190b, and a bottom surface 190c. As shown in FIG. 7, the pair of side surfaces 190a and 190b are spaced apart and face away from each other in the longitudinal direction of the electronic component 19. In the illustrated example, the electronic components 19 include those with the perpendicular direction being the first direction x and those with the perpendicular direction being the second direction y. Among the electronic components 19, the longitudinal direction of each of the first electronic components 19A, each of the second electronic components 19B, each of the electronic components 19C, and each of the electronic components 19D is the first direction x. As shown in FIG. 7, the bottom surface 190c is connected to each of the pair of side surfaces 190a and 190b, and is flanked by them. The bottom surface 190c faces downward in the thickness direction z to face the support member 2. The body 190 includes an upper surface facing upward in the thickness direction z, a side surface facing a first side in a transverse direction, and a side surface facing a second side in the transverse direction, in addition to the pair of side surfaces 190a and 190b and the bottom surface 190c.

As shown in FIGS. 2, 3, 6, and 7, the pair of terminals 191 and 192 are disposed on the respective sides of the body 190 in the longitudinal direction. In each electronic component 19, the terminal 191 is disposed at the end on a first side in the longitudinal direction, and the terminal 192 is disposed on the end on a second side in the longitudinal direction.

As shown in FIG. 7, the terminal 191 includes a side electrode 191a and a bottom electrode 191b. The side electrode 191a covers the entirety of the side surface 190a. Thus, the side electrode 191a extends from the edge of the side surface 190a on the upper side (first side) in the thickness direction z to the edge of the side surface 190a on the lower side (second side) in the thickness direction z. The bottom electrode 191b covers a part of the bottom surface 190c. The bottom electrode 191b covers the area of the bottom surface 190c near the edge thereof on the first side in the longitudinal direction. The bottom electrode 191b is connected to the side electrode 191a. The terminal 191 includes a portion covering a part of the upper surface of the body 190, a portion covering a part of the side surface of the body 190 facing the first side in the transverse direction, and a portion covering a part of the side surface of the body 190 facing the second side in the transverse direction, in addition to the side electrode 191a and the bottom electrode 191b. In the present disclosure, the boundary between the side electrode 191a and the bottom electrode 191b is defined with reference to the bottom surface 190c, where the upper side in the thickness direction z corresponds to the side electrode 191a and the lower side in the thickness direction z corresponds to the bottom electrode 191b.

As shown in FIG. 7, the terminal 192 includes a side electrode 192a and a bottom electrode 192b. The side electrode 192a covers the entirety of the side surface 190b. Thus, the side electrode 192a extends from the edge of the side surface 190b on the upper side (first side) in the thickness direction z to the edge of the side surface 190b on the lower side (second side) in the thickness direction z. The bottom electrode 192b covers a part of the bottom surface 190c. The bottom electrode 192b covers the area of the bottom surface 190c near the edge thereof on the second side in the longitudinal direction. The bottom electrode 192b is connected to the side electrode 192a. The terminal 192 includes a portion covering a part of the upper surface of the body 190, a portion covering a part of the side surface of the body 190 facing the first side in the transverse direction, and a portion covering a part of the side surface of the body 190 facing the second side in the transverse direction, in addition to the side electrode 192a and the bottom electrode 192b. In the present disclosure, the boundary between the side electrode 192a and the bottom electrode 192b is defined with reference to the bottom surface 190c, where the upper side in the thickness direction z corresponds to the side electrode 192a and the lower side in the thickness direction z corresponds to the bottom electrode 192b.

As shown in FIGS. 2 and 6 to 10, the support member 2 supports the semiconductor element 1 and the electronic components 19. The support member 2 contains a resin material, for example. The resin material is the same as the sealing resin 6 in one example, but may be different from the sealing resin 6 in another example. The support member 2 may contain a filler, such as silica, mixed with the resin material. The support member 2 may contain a single-crystal intrinsic semiconductor (e.g., silicon (Si)) instead of a resin material. As shown in FIGS. 2, 4, and 5, the support member 2 has a rectangular shape in plan view. The thickness (the dimension in the thickness direction z) of the support member 2 is not particularly limited, but may be at least 30 μm and at most 200 μm. The support member 2 has a support surface 21, a reverse surface 22, and a plurality of side surfaces 23.

As shown in FIGS. 6, 8, and 9, the support surface 21 and the reverse surface 22 are spaced apart from each other in the thickness direction z. The support surface 21 and the reverse surface 22 face away from each other. The support surface 21 is the upper surface of the support member 2, and the reverse surface 22 is the lower surface of the support member 2. The support surface 21 faces the semiconductor element 1 (the element obverse surface 10a). The reverse surface 22 faces a wiring board when the electronic device A10 is mounted on the wiring board. In the present embodiment, the support surface 21 is covered with the sealing resin 6, and the reverse surface 22 is exposed from the sealing resin 6.

As shown in FIGS. 2, 4 to 6, 8 and 9, the side surfaces 23 are located between the support surface 21 and the reverse surface 22. The upper end of each side surface 23 in the thickness direction z is connected to the support surface 21, and the lower end of each side surface 23 in the thickness direction z is connected to the reverse surface 22. Each side surface 23 is flat and perpendicular to the support surface 21 and the reverse surface 22.

The wiring layer 3 is a conductor disposed in the electronic device A10. The wiring layer 3 contains Cu, for example. The wiring layer 3 may be a laminate including a seed layer (that contains titanium (Ti), for example) and a metal layer (that contains Cu, for example), or may be a single layer made of a conductor. As shown FIGS. 2 and 3, the wiring layer 3 includes a plurality of wiring sections 30. The wiring sections 30 are separated from each other. The wiring sections 30 include one electrically connected to the semiconductor element 1, one electrically connected to one of the electronic components 19, and one not electrically connected to either the semiconductor element 1 or any of the electronic components 19. In the present embodiment, the wiring layer 3 is formed on the support surface 21, and is in contact with the support surface 21. The thickness (the dimension in the thickness direction z) of the wiring layer 3 is at least 3 μm and at most 100 μm.

As shown in FIGS. 2 to 4, 6, and 7, the wiring sections 30 include a first wiring section 31, a second wiring section 32, and a third wiring section 33. The first wiring section 31, the second wiring section 32, and the third wiring section 33 are spaced apart from each other.

The terminals 191 of the two first electronic components 19A are bonded to the first wiring section 31 via conductive bonding members 42. Thus, the terminals 191 of the two first electronic components 19A are electrically connected to each other via the first wiring section 31. The terminals 192 of the two second electronic components 19B are bonded to the first wiring section 31 via conductive bonding members 42. Thus, the terminals 192 of the two second electronic components 19B are electrically connected to each other via the first wiring section 31. The terminals 191 of the two first electronic components 19A and the terminals 192 of the two second electronic components 19B are electrically connected to each other via the first wiring section 31. As shown in FIGS. 2 to 4, the first wiring section 31 is not electrically connected to either the semiconductor element 1 or the outer terminals 5, unless the connection is made through one of the two first electronic components 19A and the two second electronic components 19B. In other words, the first wiring section 31 is electrically connected to the semiconductor element 1 and an outer terminal 5 via one of the two first electronic components 19A and the two second electronic components 19B.

As shown in FIGS. 3 and 10, the first wiring section 31 includes a plurality of partitioned areas 311 and a connecting area 312. In the present embodiment, the first wiring section 31 includes two partitioned areas 311. The two partitioned areas 311 are spaced apart from each other. The terminal 191 of one of the two first electronic components 19A and the terminal 192 of one of the two second electronic components 19B are bonded to one of the two partitioned areas 311. The terminal 191 of the other of the two first electronic components 19A and the terminal 192 of the other of the two second electronic components 19B are bonded to the other of the two partitioned areas 311. In the example shown in FIGS. 3 and 10, the two partitioned areas 311 are spaced apart from each other in the second direction y. The connecting area 312 is located between the two partitioned areas 311. The connecting area 312 is connected to the two partitioned areas 311, and electrically connects the two partitioned areas 311.

The terminals 192 of the two first electronic components 19A are bonded to the second wiring section 32 via conductive bonding members 42. Thus, the terminals 192 of the two first electronic components 19A are electrically connected to each other via the second wiring section 32. In the example shown in FIGS. 2 to 4, the second wiring section 32 is electrically connected to one of the outer terminals 5.

The terminals 191 of the two second electronic components 19B are bonded to the third wiring section 33 via conductive bonding members 42. Thus, the terminals 191 of the two second electronic components 19B are electrically connected to each other via the third wiring section 33. In the example shown in FIGS. 2 to 4, the third wiring section 33 is electrically connected to one of the outer terminals 5 and to the semiconductor element 1.

In the illustrated example, the first wiring section 31, the second wiring section 32, and the third wiring section 33 are disposed in the first direction x. The first wiring section 31 is located between the second wiring section 32 and the third wiring section 33 in the first direction x. The second wiring section 32 is offset to a second side in the first direction x relative to the first wiring section 31, and the third wiring section 33 is offset to a first side in the first direction x relative to the first wiring section 31.

Each of the two first electronic components 19A is disposed across the first wiring section 31 and the second wiring section 32. The two first electronic components 19A are disposed in the second direction y, and overlap with each other as viewed in the second direction y. Each of the two second electronic components 19B is disposed across the first wiring section 31 and the third wiring section 33. The two second electronic components 19B are disposed in the second direction y, and overlap with each other as viewed in the second direction y. The two first electronic components 19A and the two second electronic components 19B are disposed in the first direction x. As viewed in the first direction x, the two first electronic components 19A overlap with the two second electronic components 19B, respectively. Note that the two first electronic components 19A and the two second electronic components 19B may be offset as long as their electrical connections remain the same. For example, misalignment of the two first electronic components 19A and the two second electronic components 19B may occur as a result of manufacturing errors.

As shown in FIG. 2, the wiring sections 30 include a plurality of wiring sections 34, 35, and 36. The wiring sections 34, 35, 36 are spaced apart from each other.

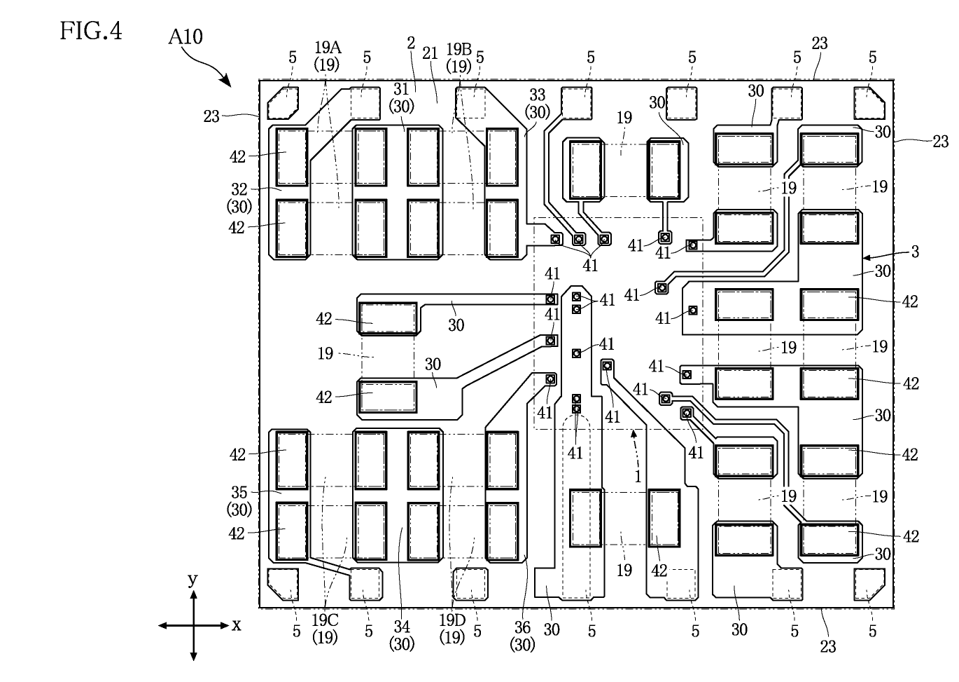

The terminals 191 of the two electronic components 19C are bonded to the wiring section 34 via conductive bonding members 42. Thus, the terminals 191 of the two electronic components 19C are electrically connected to each other via the wiring section 34. The terminals 192 of the two electronic components 19D are bonded to the wiring section 34 via conductive bonding members 42. Thus, the terminals 192 of the two electronic components 19D are electrically connected to each other via the wiring section 34. The terminals 191 of the two electronic components 19C and the terminals 192 of the two electronic components 19D are electrically connected to each other via the wiring section 34. As shown in FIGS. 2 and 4, the wiring section 34 is not electrically connected to either the semiconductor element 1 or the outer terminals 5, unless the connection is made through one of the electronic components 19C and 19D. In other words, the wiring section 34 is electrically connected to the semiconductor element 1 and an outer terminal 5 via one of the electronic components 19C and 19D. Although the details are omitted, as with the first wiring section 31, the wiring section 34 includes a plurality of partitioned areas and a connecting area.

The terminals 192 of the two electronic components 19C are bonded to the wiring section 35 via conductive bonding members 42. Thus, the terminals 192 of the two electronic components 19C are electrically connected to each other via the wiring section 35. In the example shown in FIGS. 2 and 4, the wiring section 35 is electrically connected to one of the outer terminals 5.

The terminals 191 of the two electronic components 19D are bonded to the wiring section 36 via conductive bonding members 42. Thus, the terminals 191 of the two electronic components 19D are electrically connected to each other via the wiring section 36. In the example shown in FIGS. 2 and 4, the wiring section 36 is electrically connected to the semiconductor element 1.

In the illustrated example, the wiring sections 34, 35, and 36 are disposed in the first direction x. The wiring section 34 is located between the wiring section 35 and the wiring section 36 in the first direction x. The wiring section 35 is offset to the second side in the first direction x relative to the wiring section 34, and the wiring section 36 is offset to the first side in the first direction x relative to the wiring section 34.

Each of the two electronic components 19C is disposed across the wiring section 34 and the wiring section 35. The two electronic components 19C are disposed in the second direction y, and overlap with each other as viewed in the second direction y. Each of the two electronic components 19D is disposed across the wiring section 34 and the wiring section 36. The two electronic components 19D are disposed in the second direction y, and overlap with each other as viewed in the second direction y. The two electronic components 19C and the two electronic components 19D are disposed in the first direction x. As viewed in the first direction x, the two electronic components 19C overlap with the two electronic components 19D, respectively. Note that the two electronic components 19C and the two electronic components 19D may be offset as long as their electrical connections remain the same. For example, misalignment of the two electronic components 19C and the two electronic components 19D may occur as a result of manufacturing errors.

As will be understood from FIGS. 4, 6 and 8, each of the conductive bonding members 41 bonds the wiring layer 3 and one of the electrode pads 14 of the semiconductor element 1. The semiconductor element 1 is electrically connected to the wiring layer 3 via the conductive bonding members 41. Each of the conductive bonding members 41 is made of a conductive bonding material. For example, the conductive bonding members 41 are made of solder. The solder contains an alloy containing tin (Sn) (e.g., Sn-silver (Ag) alloy), and also contains flux. Note that the composition of each conductive bonding member 41 is not limited to this example. The thickness (the dimension in the thickness direction z) of each conductive bonding member 41 is not particularly limited, but may be at least 15 μm and at most 100 μm.

As shown in FIGS. 4, 6, 8, and 9, each of the conductive bonding members 42 bonds the wiring layer 3 (one of the wiring sections 30) and a corresponding one of the pair of terminals 191 and 192 of an electronic component 19. Each of the conductive bonding members 42 is made of a conductive bonding material. For example, the conductive bonding members 42 are made of solder. The solder contains an alloy containing tin (Sn) (e.g., Sn-silver (Ag) alloy). Each of the conductive bonding members 42 may or may not contain flux. The thickness (the dimension in the thickness direction z) of each conductive bonding member 42 is not particularly limited, but may be at least 1 μm and at most 20 μm.

As shown in FIGS. 7 or 10, each of the conductive bonding members 42 includes a fillet portion 421. The fillet portion 421 is in contact with either the side electrode 191a of the terminal 191 of an electronic component 19 or the side electrode 192a of the terminal 192 of the electronic component 19. In the example shown in FIGS. 7 or 10, the side surface of the fillet portion 421 is curved outward. However, in another example, the side surface of the fillet portion 421 may be curved inward or may not be curved at all.

The outer terminals 5 are conductors electrically connected to the wiring layer 3 and exposed to the outside of the electronic device A10. The outer terminals 5 are terminals used when the electronic device A10 is mounted onto a wiring board. As shown in FIGS. 6 and 8 to 10, the outer terminals 5 penetrate through the support member 2 in the thickness direction z. The outer terminals 5 include one electrically connected to the semiconductor element 1 via the wiring layer 3, one electrically connected to the semiconductor element 1 and one of the electronic components 19 via the wiring layer 3, one electrically connected to one of the electronic components 19 via the wiring layer 3, and one not electrically connected to either the semiconductor element 1 or any of the electronic components 19. In the illustrated example, each of the outer terminals 5 is disposed outside the semiconductor element 1 in plan view, and does not overlap with either the semiconductor element 1 or any of the electronic components 19 in plan view. Unlike this example, some of the outer terminals 5 may each overlap with either the semiconductor element 1 or one of the electronic components 19 in plan view.

As shown in FIGS. 6 and 8 to 10, each of the outer terminals 5 includes a columnar portion 51 and an external electrode portion 52. Unless otherwise specified, the description of the columnar portion 51 and the external electrode portion 52 given below applies to each of the outer terminals 5.

As shown in FIGS. 6 and 8 to 10, the columnar portion 51 penetrates through the support member 2 in the thickness direction z. The columnar portion 51 contains a metal material, for example. The metal material is not particularly limited, but may be Cu. The shape of the columnar portion 51 in plan view is not particularly limited, but may be a rectangle or a polygon in the illustrated example. The upper surface (the surface facing upward in the thickness direction z) of the columnar portion 51 is flush with the support surface 21 of the support member 2, for example. The upper surface of the columnar portion 51 is in contact with the wiring layer 3. Note that the outer terminals 5 may include one having a columnar portion 51 whose upper surface is not in contact with the wiring layer 3. Such an outer terminal 5 serves as a dummy terminal. The lower surface (the surface facing downward in the thickness direction z) of the columnar portion 51 is exposed from the support member 2. The lower surface of the columnar portion 51 is flush with the reverse surface 22 of the support member 2, for example. In the present embodiment, the columnar portion 51 of each outer terminal 5 has side surfaces (each facing in the first direction x or in the second direction y) covered with the support member 2. Unlike this example, the columnar portions 51 of some of the outer terminals 5 may have side surfaces exposed to the outside.

As shown in FIGS. 6 and 8 to 10, the external electrode portion 52 is in contact with a part of the columnar portion 51 that is exposed from the reverse surface 22 of the support member 2. The external electrode portion 52 protrudes from the reverse surface 22. The external electrode portion 52 is formed by electroless plating. In one example, the external electrode portion 52 is made up of a plurality of metal layers stacked in the order of an Ni layer, a palladium (Pd) layer, and a gold (Au) layer, starting from the side in contact with the columnar portion 51. In another example, the external electrode portion 52 may be made up of a plurality of metal layers stacked in the order of an Ni layer and an Au layer or a plurality of metal layers stacked in the order of a Cu layer, an Ag layer, and an Sn layer, starting from the side in contact with the columnar portion 51. The material and formation method of the external electrode portion 52 are not limited to these examples.

The sealing resin 6 is made of a synthetic resin mainly containing black epoxy resin, for example. The epoxy resin in the sealing resin 6 may be mixed with a filler such as silica. As shown in FIGS. 2 and 6 to 10, the sealing resin 6 covers elements such as the semiconductor element 1, the electronic components 19, and the wiring layer 3. As shown in FIGS. 2 and 6 to 10, the sealing resin 6 also covers a part of the support member 2, the conductive bonding members 41, and the conductive bonding members 42. The sealing resin 6 is formed on the support surface 21. The sealing resin 6 has a rectangular shape in plan view. As shown in FIGS. 1, 2, and 5 to 10, the sealing resin 6 has a resin obverse surface 61, a resin reverse surface 62, and a plurality of resin side surfaces 63.

As shown in FIGS. 6 to 10, the resin obverse surface 61 and the resin reverse surface 62 are spaced apart from each other in the thickness direction z. The resin obverse surface 61 and the resin reverse surface 62 face away from each other in the thickness direction z. The resin obverse surface 61 faces the same side as the support surface21 in the thickness direction z, and the resin reverse surface 62 faces the same side as the reverse surface 22 in the thickness direction z. The resin reverse surface 62 is in contact with the support surface21. The resin reverse surface 62 has recesses and protrusions corresponding to the shape of the wiring layer 3. As shown in FIGS. 6, 8, and 9, the resin side surfaces 63 are located between the resin obverse surface 61 and the resin reverse surface 62 in the thickness direction z, and are connected to these surfaces. The resin side surfaces 63 are flush with the respective side surfaces 23.

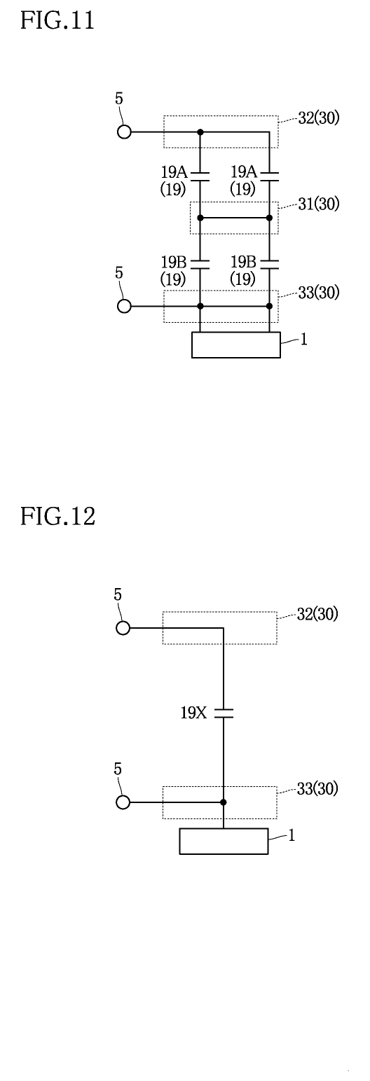

The following describes examples of circuit configurations for the electronic device A10 with reference to FIGS. 11 and 12. Each of the circuit configurations in FIGS. 11 and 12 shows the connection between the two first electronic components 19A and the two second electronic components 19B, assuming that each electronic component 19 is a capacitor. The circuit diagram of FIG. 11 shows the connection as described in the example of the configuration shown in FIGS. 1 to 10. The circuit diagram of FIG. 12 is an equivalent representation of the circuit diagram shown in FIG. 11.

As shown in the circuit diagram of FIG. 11, in the electronic device A10, the two first electronic components 19A are electrically connected in parallel between the first wiring section 31 and the second wiring section 32. The two second electronic components 19B are electrically connected in parallel between the first wiring section 31 and the third wiring section 33. The two first electronic components 19A are connected to the two second electronic components 19B in series via the first wiring section 31.

On the other hand, in the circuit diagram shown in FIG. 12, the electrical characteristics (capacitances) of the two first electronic components 19A and the two second electronic components 19B are combined and equivalently represented as a single electronic component 19X between the second wiring section 32 and the third wiring section 33. In other words, in the electronic device A10, the electrical characteristics of the two first electronic components 19A and the two second electronic components 19B are equivalently represented by a single circuit symbol (electronic component 19X) in the circuit diagram.

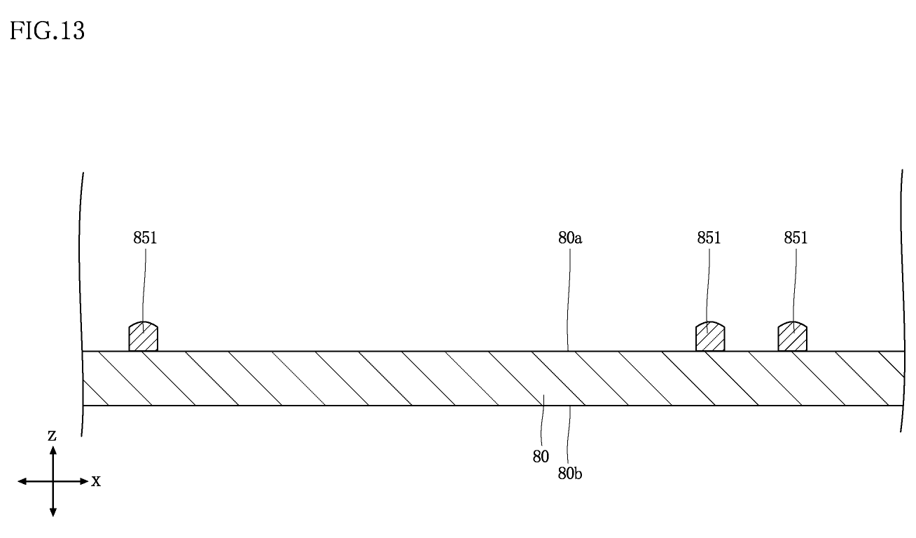

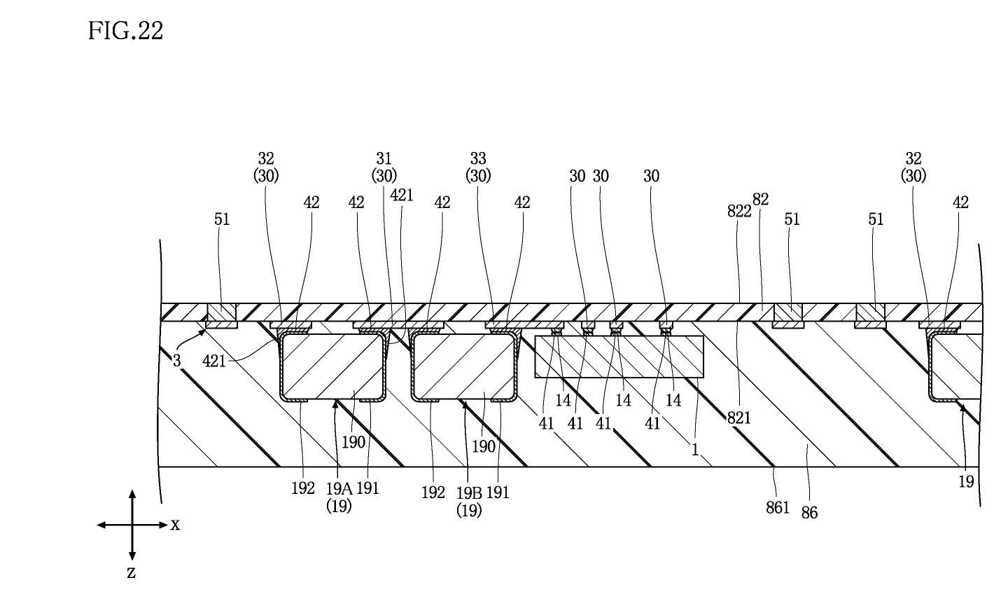

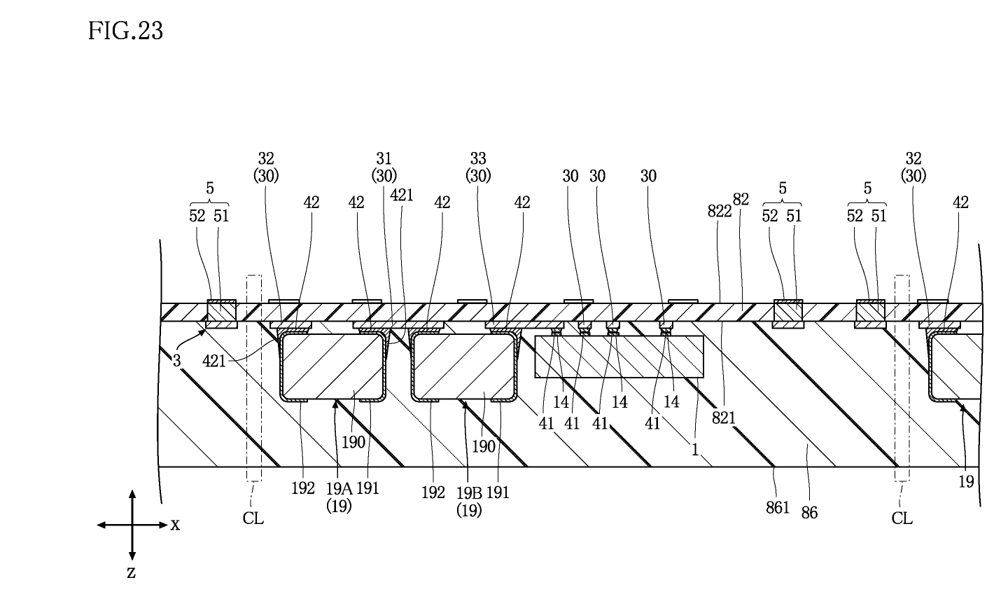

The following describes an example of a method for manufacturing the electronic device A10, with reference to FIGS. 13 to 23. FIGS. 13 to 23 are cross-sectional views each showing a step of the method for manufacturing the electronic device A10. These cross-sectional views are taken along the same line as in FIG. 6. The cross-sectional views in FIGS. 22 and 23 are reversed in the thickness direction z as compared to the cross-sectional views of FIGS. 13 to 21.

First, as shown in FIG. 13, a support substrate 80 is prepared, and a plurality of columnar conductors 851 are formed on the support substrate 80. The support substrate 80 contains a single-crystal intrinsic semiconductor material, for example. The semiconductor material is Si, for example. In the step of preparing the support substrate 80, a silicon wafer, which serves as the support substrate 80, may be prepared. The support substrate 80 has a substrate obverse surface 80a and a substrate reverse surface 80b that face away from each other in the thickness direction z. The columnar conductors 851 may be formed through the following steps. First, a seed layer is formed on the substrate obverse surface 80a. The seed layer may be formed by sputtering. Next, a resist is patterned on the seed layer to form the columnar conductors 851 by electroplating. Then, the resist and unnecessary parts of the seed layer are removed. Through the steps described above, the columnar conductors 851 are formed on the substrate obverse surface 80a of the support substrate 80. The columnar conductors 851 will be formed into the columnar portions 51 of the outer terminals 5 in a subsequent step.

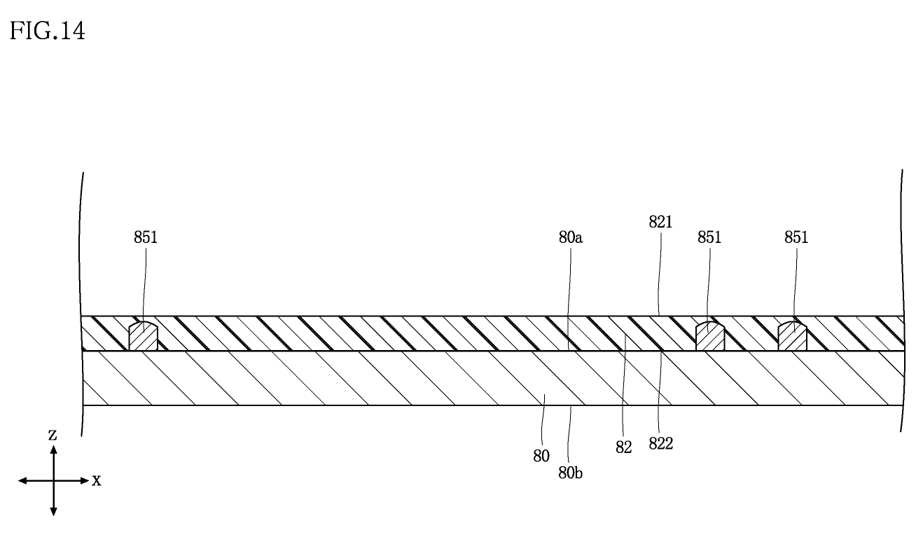

Next, as shown in FIG. 14, a first resin layer 82 is formed on the substrate obverse surface 80a of the support substrate 80 to cover the columnar conductors 851. The first resin layer 82 is formed by molding, for example. The first resin layer 82 is made of a synthetic resin mainly containing black epoxy resin, for example. The first resin layer 82 may be made of another insulating resin material instead of the synthetic resin. The first resin layer 82 has an obverse surface 821 and a bottom surface 822 that face away from each other in the thickness direction z. The obverse surface 821 faces in the same direction as the substrate obverse surface 80a, and the bottom surface 822 faces the substrate obverse surface 80a. The first resin layer 82 will be formed into the support member 2 in a subsequent step.

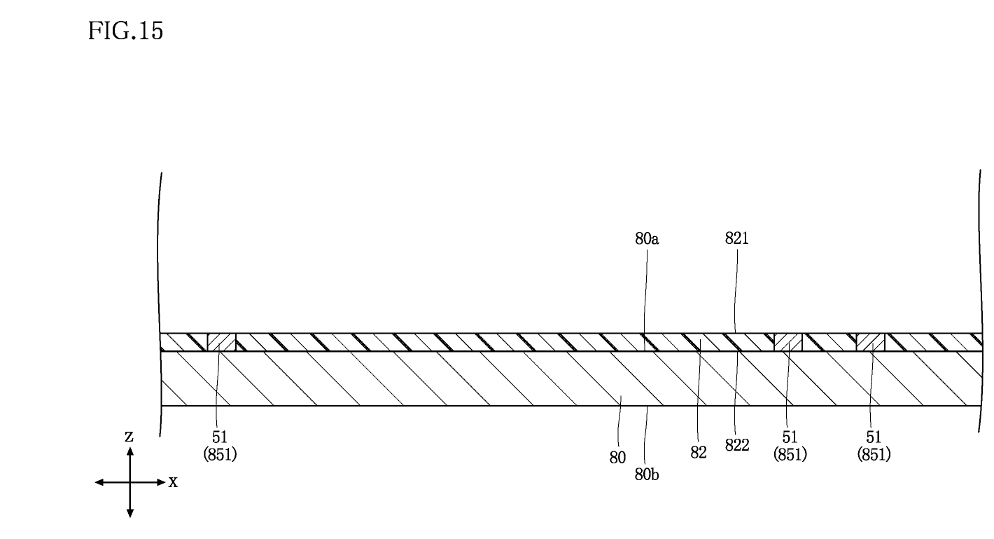

Next, as shown in FIG. 15, the first resin layer 82 is ground. The grinding of the first resin layer 82 is performed from the obverse surface 821 side until the columnar conductors 851 are exposed from the obverse surface 821. A method for the grinding is not particularly limited. In addition, a method other than grinding can be selected to reduce the height of the first resin layer 82. As a result, the columnar portions 51 are formed from the columnar conductors 851.

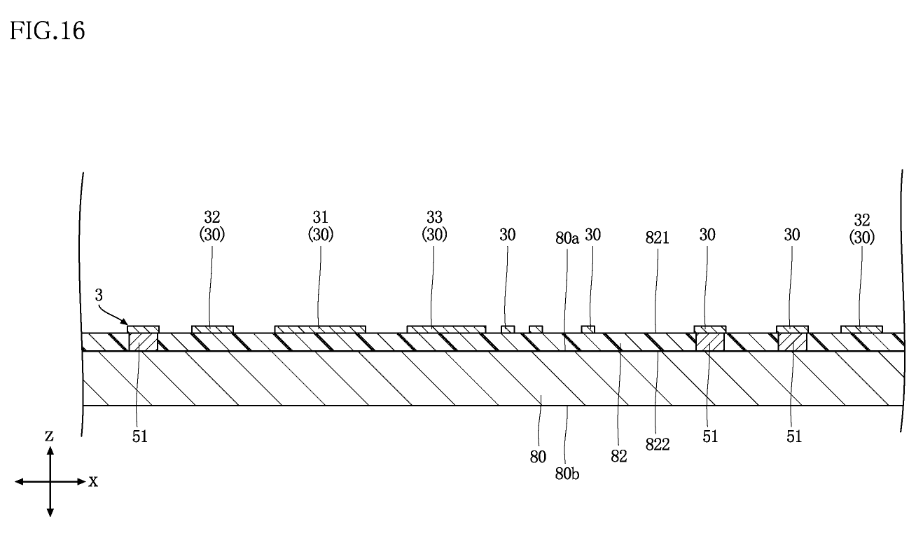

Next, as shown in FIG. 16, the wiring layer 3 is formed. The wiring layer 3 is formed through the following steps. First, a seed layer is formed on the obverse surface 821 and the columnar portions 51. The seed layer may be formed by sputtering. For example, a Ti layer and a Cu layer are stacked in sequence to form a seed layer. Then, a resist is patterned on the seed layer, and a metal layer is formed by electroplating. For example, the metal layer contains Cu. Subsequently, the resist and unnecessary parts of the seed layer (i.e., parts exposed from the metal layer) are removed. Through these steps, the wiring layer 3 is formed.

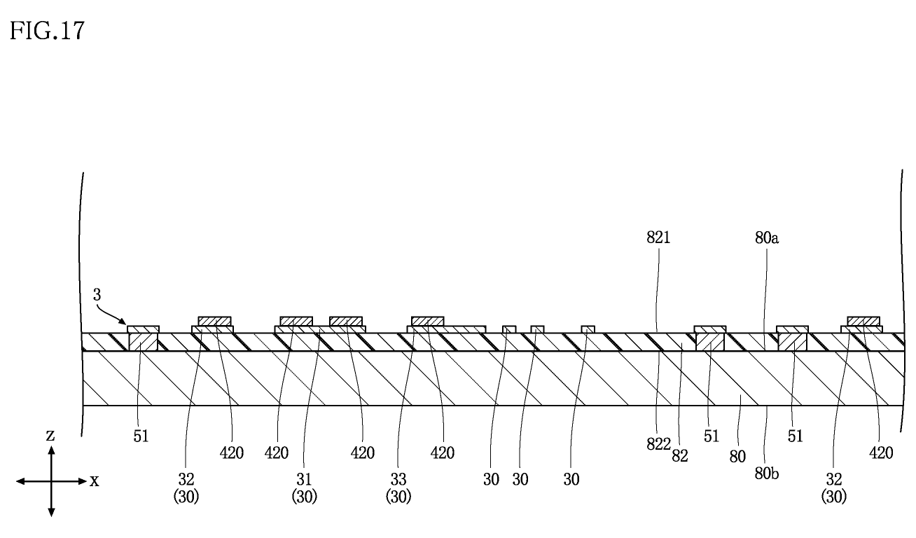

Next, as shown in FIG. 17, a plurality of conductive bonding members 420 are formed. In the step of forming the conductive bonding members 420, solder paste serving as each of the conductive bonding members 420 is formed on corresponding wiring sections 30 (the wiring layer 3) by screen printing. Note that the method for forming the conductive bonding members 420 is not limited to this. The corresponding wiring sections 30 refer to wiring sections 30, out of the plurality of wiring sections 30, to which the electronic components 19 are to be bonded.

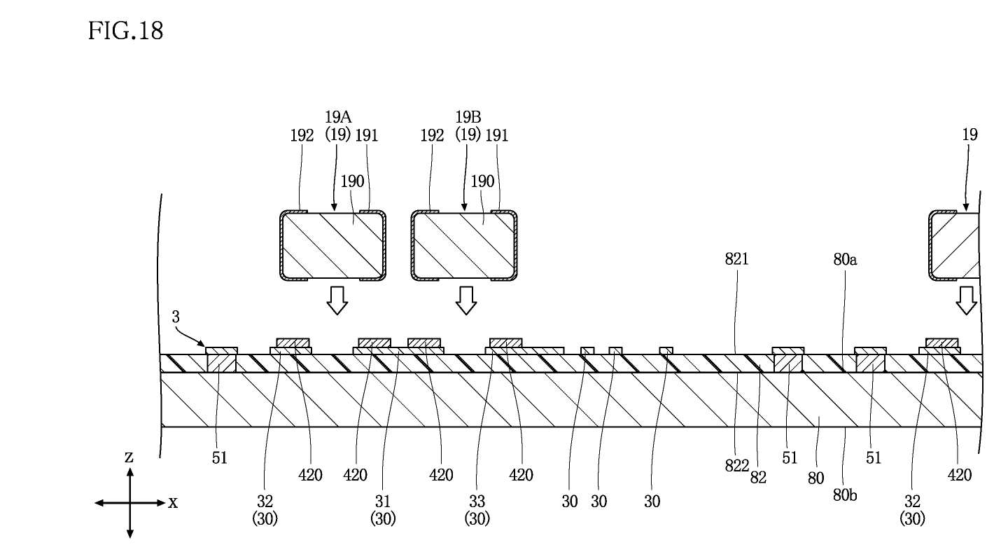

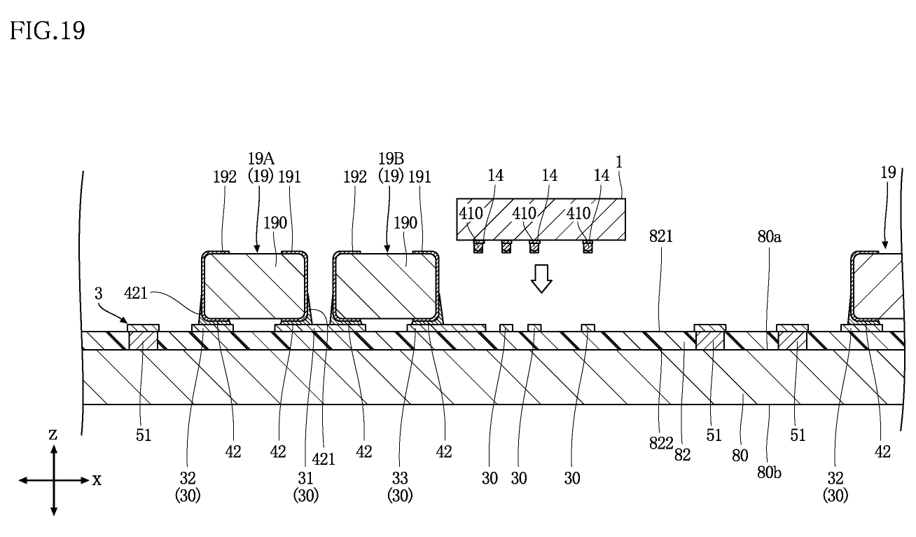

Next, as shown in FIGS. 18 and 19, the electronic components 19 are mounted and then bonded. As shown in FIG. 18, in the step of mounting the electronic components 19, the terminals 191 of the electronic components 19 are placed in correspondence with the conductive bonding members 420. Next, reflow is performed in the state where the electronic components 19 are placed. Heat from the reflow causes the conductive bonding members 420 to melt. Next, the melted conductive bonding members 420 are cooled and solidified to become the conductive bonding members 42. As a result, the electronic components 19 are bonded by the conductive bonding members 42. As shown in FIG. 19, a fillet portion 421 is formed in each of the conductive bonding members 42.

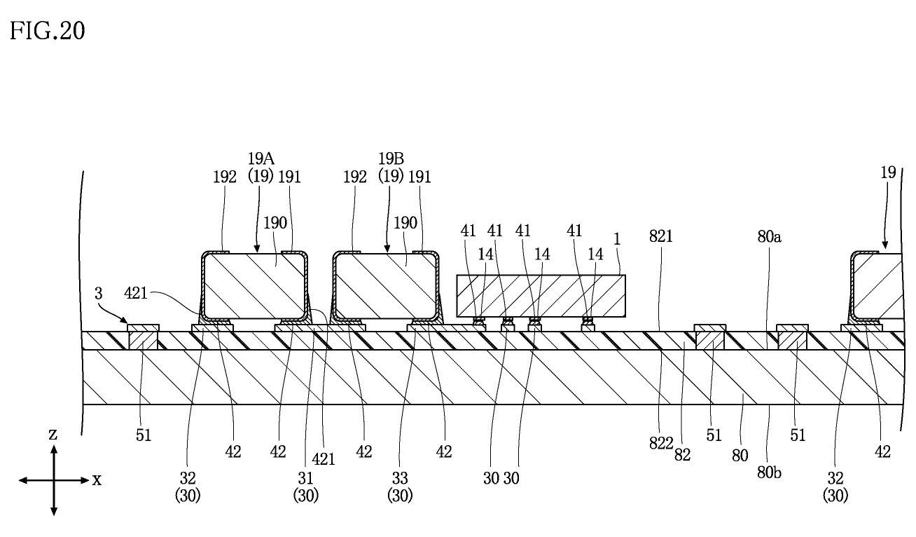

Next, as shown in FIGS. 19 and 20, the semiconductor element 1 is mounted and then bonded. As shown in FIG. 19, in the step of mounting the semiconductor element 1, conductive bonding members 410 formed on the semiconductor element 1 are placed in correspondence with the wiring layer 3 (some wiring sections 30). In the present embodiment, the conductive bonding members 410 are formed on the electrode pads 14 of the semiconductor element 1. However, the conductive bonding members 410 may be formed on corresponding wiring sections 30 (the wiring layer 3) instead. The corresponding wiring sections 30 refer to wiring sections 30, out of the plurality of wiring sections 30, to which the semiconductor element 1 is to be bonded. Each of the conductive bonding members 410 formed on the semiconductor element 1 contains flux. Next, reflow is performed in the state where the semiconductor element 1 is placed. Heat from the reflow causes the conductive bonding members 410 to melt. Next, the melted conductive bonding members 410 are cooled and solidified to become the conductive bonding members 41. As a result, the semiconductor element 1 is bonded by the conductive bonding members 41.

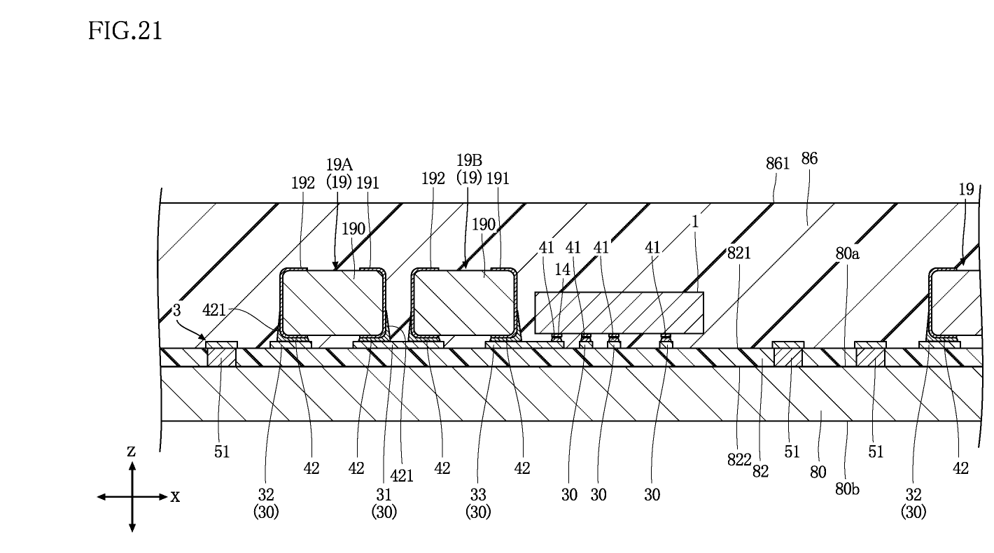

Next, as shown in FIG. 21, a second resin layer 86 is formed. The second resin layer 86 is formed over the support member 2 to cover the semiconductor element 1, the electronic components 19, and the wiring layer 3. The second resin layer 86 is formed by molding, for example. The second resin layer 86 is made of a synthetic resin mainly containing black epoxy resin, for example. The second resin layer 86 may be made of another insulating resin material instead of the synthetic resin. The second resin layer 86 will be formed into the sealing resin 6 in a subsequent step. The second resin layer 86 has a top surface 861 facing a first side in the thickness direction z. The top surface 861 corresponds to the resin obverse surface 61 of the sealing resin 6.

Next, as shown in FIG. 22, the support substrate 80 is removed. In the step of removing the support substrate 80, for example, the support substrate 80 may be ground from the substrate reverse surface 80b side in the state shown in FIG. 21. In this grinding step, the support substrate 80 is ground from the substrate reverse surface 80b side. In the illustrated example, the grinding is performed continuously even after the support substrate 80 is removed so as to reduce the height of each of the support member 2 and the columnar portions 51. This height reduction may be omitted.

Next, as shown in FIG. 23, the external electrode portions 52 are formed. The external electrode portions 52 are formed on the top surfaces of the columnar portions 51 that are exposed from the reverse surface 22. The external electrode portions 52 are formed by electroless plating, for example. In the electroless plating, an Ni layer, a Pd layer, and an Au layer are stacked in this order to form each external electrode portion 52 from the side in contact with a corresponding columnar portion 51. As a result, the outer terminals 5, each including a columnar portion 51 and an external electrode portion 52, are formed.

Subsequently, the second resin layer 86 is cut along cut lines CL shown in FIG. 23 and divided into individual pieces. The cutting of the second resin layer 86 may be performed by a dicing process with a dicing blade. The sealing resin 6 of the electronic device A10 is formed by dividing the second resin layer 86 at the cut lines CL.

The electronic device A10 shown in FIGS. 1 to 10 is manufactured through the steps as described above. The manufacturing method of the electronic device A10 is not limited to the above example. For example, the electronic device A10 is manufactured as follows when the support member 2 contains a single-crystal intrinsic semiconductor (e.g., Si). First, grooves are formed in the support substrate 80 (silicon wafer) by etching or the like. Next, the columnar conductors 851 are formed in the grooves. Then, the wiring layer 3 is formed without forming the first resin layer 82. After the second resin layer 86 is formed, the support substrate 80 is not removed but rather ground until the columnar conductors 851 in the grooves are exposed.

The functions and advantages of the electronic device A10 are as follows.

In the electronic device A10, the wiring layer 3 includes the first wiring section 31 to which either the terminal 191 or 192 of each of a plurality of electronic components 19 is bonded. The electrical characteristics of the electronic components 19 are equivalently represented by a single circuit symbol in a circuit diagram. With this configuration, the electrical characteristic of a single electronic component is designed as the combined value of the electrical characteristics of a plurality of electronic components 19 (the two first electronic components 19A and the two second electronic components 19B in the present embodiment). Thus, various electrical characteristic values can be obtained by combinations of a plurality of electronic components. This makes it possible to design the electronic device A10 with highly accurate electrical specifications. Further, in a configuration different from that of the electronic device A10, such as the circuit configuration shown in FIG. 12, necessary electrical characteristics may be achieved by the single electronic component 19X between the second wiring section 32 and the third wiring section 33. In this case, the size (e.g., thickness) of the electronic component 19X increases. As a result, the thickness (the dimension in the thickness direction z) of the sealing resin 6 increases, and the stress applied by the sealing resin 6 to the support member 2 may cause the warpage of the support member 2. In other words, the smaller the thickness of the sealing resin 6, the smaller the warpage of the support member 2. In contrast, in the electronic device A10, the electrical characteristic of a single electronic component is designed as the combined value of the electrical characteristics of a plurality of electronic components 19. This allows the single electronic component 19X to be replaced with a plurality of electronic components 19 that are thinner (have smaller thickness) than the electronic component 19X. Thus, the electronic device A10 can be designed with a thinner sealing resin 6. Such thinning is preferable for reducing the warpage of the support member 2, as described above. For the reasons given above, the electronic device A10 can improve flexibility in module design.

The wiring layer 3 of the electronic device A10 includes the first wiring section 31, the second wiring section 32, and the third wiring section 33. The electronic components 19 include a first electronic component 19A and a second electronic component 19B. The first electronic component 19A has a pair of terminals 191 and 192 that are bonded to the first wiring section 31 and the second wiring section 32, respectively. The second electronic component 19B has a pair of terminals 191 and 192 that are bonded to the third wiring section 33 and the first wiring section 31, respectively. With this configuration, the second wiring section 32 and the third wiring section 33 are electrically connected to the first electronic component 19A and the second electronic component 19B via the first wiring section 31. In other words, electrical characteristics equivalently represented by a single circuit symbol between the second wiring section 32 and the third wiring section 33 can be designed with at least one first electronic component 19A and at least one second electronic component 19B.

In the electronic device A10, the first wiring section 31 is electrically connected to the semiconductor element 1 or a plurality of outer terminals 5 via one of the electronic components 19 (the two first electronic components 19A and the two second electronic components 19B). With this configuration, the first wiring section 31 is not directly electrically connected to either the semiconductor element 1 or the outer terminals 5. Thus, in a configuration where a single electronic component can electrically connect the second wiring section 32 and the third wiring section 33, the provision of the first wiring section 31 enables the second wiring section 32 and the third wiring section 33 to be electrically connected via a series circuit made up of at least two electronic components 19 (a single first electronic component 19A and a single second electronic component 19B). In other words, the electrical characteristics equivalently represented by a single circuit symbol between the second wiring section 32 and the third wiring section 33 can be designed with a plurality of electronic components 19. This is preferable for improving flexibility in the module design of the electronic device A10.

In the electronic device A10, the first wiring section 31 includes the two partitioned areas 311 and the connecting area 312. The connecting area 312 connects the two partitioned areas 311 that are spaced apart from each other. With this configuration, the terminals 191 of the two first electronic components 19A are electrically connected to each other via the first wiring section 31. This makes it possible to electrically connect the two first electronic components 19A in parallel. Similarly, the terminals 192 of the two second electronic components 19B are electrically connected to each other via the first wiring section 31. This makes it possible to electrically connect the two second electronic components 19B in parallel.

In the electronic device A10, the first wiring section 31 has a rectangular shape in plan view. The two first electronic components 19A overlap with each other as viewed in the second direction y, and the two second electronic components 19B overlap with each other as viewed in the second direction y. As viewed in the first direction x, the two first electronic components 19A overlap with the two second electronic components 19B, respectively. This configuration can reduce the distance difference described below. In one example, the distance difference is a difference in distance between the conductive path in the first wiring section 31 that connects the terminals 191 of the two first electronic components 19A and the conductive path in the first wiring section 31 that connects the terminals 192 of the two second electronic components 19B. In another example, the distance difference is a difference in distance between the conductive path in the first wiring section 31 that connects the terminal 191 of one of the two first electronic components 19A and the terminal 192 of one of the two second electronic components 19B and the conductive path in the first wiring section 31 that connects the terminal 191 of the other first electronic component 19A and the terminal 192 of the other second electronic component 19B. The configuration described above reduces differences in the conductive paths in the first wiring section 31 among the two first electronic components 19A and the two second electronic components 19B, thereby reducing electrical variations between the two first electronic components 19A and the two second electronic components 19B.

In the electronic device A10, each of the electronic components 19 exhibits the same performance with respect to an electrical characteristic. With this configuration, it is possible, for example, to make the sizes (thicknesses and plan-view sizes) of a plurality of electronic components 19 (the first electronic components 19A and the second electronic components 19B) uniform, thereby reducing variations in the thicknesses of the electronic components 19. This facilitates the design of the thickness (the dimension in the thickness direction z) of the sealing resin 6 in the electronic device A10. It also facilitates computation of the composite electrical characteristic constituents of the electronic components 19 in the electronic device A10.

In the electronic device A10, the support member 2 contains a resin material, and the resin material is the same as the sealing resin 6. This configuration can reduce the difference between the coefficient of linear expansion of the support member 2 and the coefficient of linear expansion of the sealing resin 6, thereby suppressing the thermal stress generated in the electronic device A10.

In the electronic device A10, the wiring layer 3 includes the wiring sections 34, 35, and 36. The electronic components 19 include a plurality of electronic components 19C and 19D. The relative position and electrical connection between the wiring sections 34, 35, and 36 and the electronic components 19C and 19D are the same as those between the first wiring section 31, the second wiring section 32, and the third wiring section 33 and at least one first electronic component 19A and at least one second electronic component 19B. Thus, the functions and advantages of these elements are the same.

The following describes other embodiments and variations of the electronic device according to the present disclosure. The configurations of the elements in each of the embodiments and the variations can be combined as appropriate as long as the combination does not cause technical contradictions.

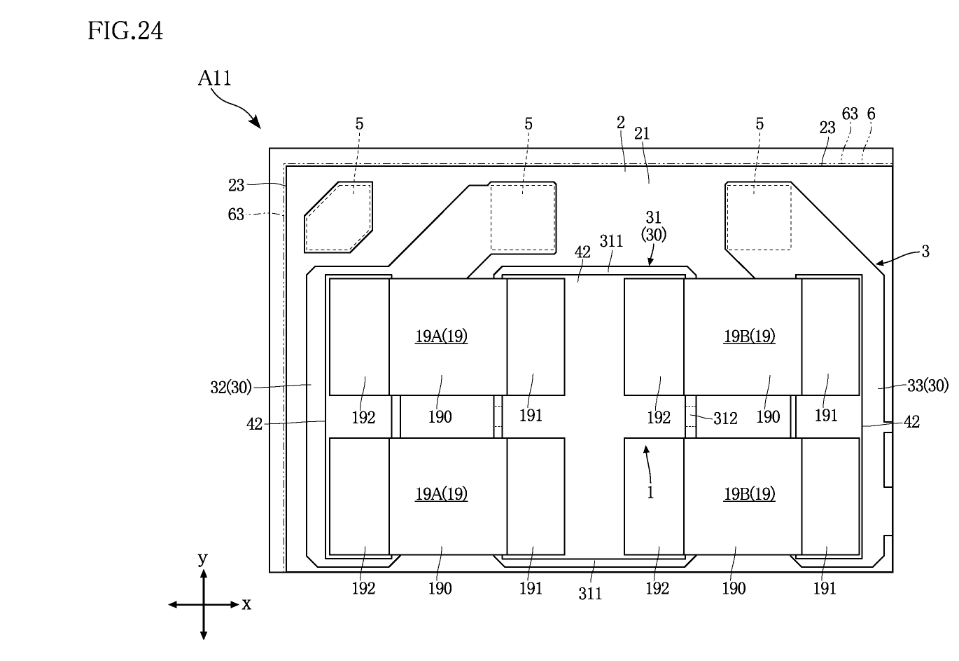

FIG. 24 shows an electronic device A11 according to a first variation of the first embodiment. The electronic device A11 is different from the electronic device A10 in the following points. First, the terminals 191 of the two first electronic components 19A and the terminals 192 of the two second electronic components 19B are bonded to the first wiring section 31 via a single conductive bonding member 42. Second, the terminals 192 of the two first electronic components 19A are bonded to the second wiring section 32 via a single conductive bonding member 42. Third, the terminals 191 of the two second electronic components 19B are bonded to the third wiring section 33 via a single conductive bonding member 42.

In the electronic device A11, the two first electronic components 19A and the two second electronic components 19B are bonded to the first wiring section 31 via a single conductive bonding member 42. In this way, the electronic device of the present disclosure is not limited to having a configuration where the first electronic components 19A and the second electronic components 19B are individually bonded to the first wiring section 31, and may have a configuration where the first electronic components 19A and the second electronic components 19B are collectively bonded to the first wiring section 31. Similarly, the two first electronic components 19A are bonded to the second wiring section 32 by a single conductive bonding member 42. In this way, the electronic device of the present disclosure is not limited to having a configuration where the two first electronic components 19A are individually bonded to the second wiring section 32, and may have a configuration where the first electronic components 19A are collectively bonded to the second wiring section 32. Similarly, the two second electronic components 19B are bonded to the third wiring section 33 by a single conductive bonding member 42. In this way, the electronic device of the present disclosure is not limited to having a configuration where the two second electronic components 19B are individually bonded to the third wiring section 33, and may have a configuration where the second electronic components 19B are collectively bonded to the third wiring section 33.

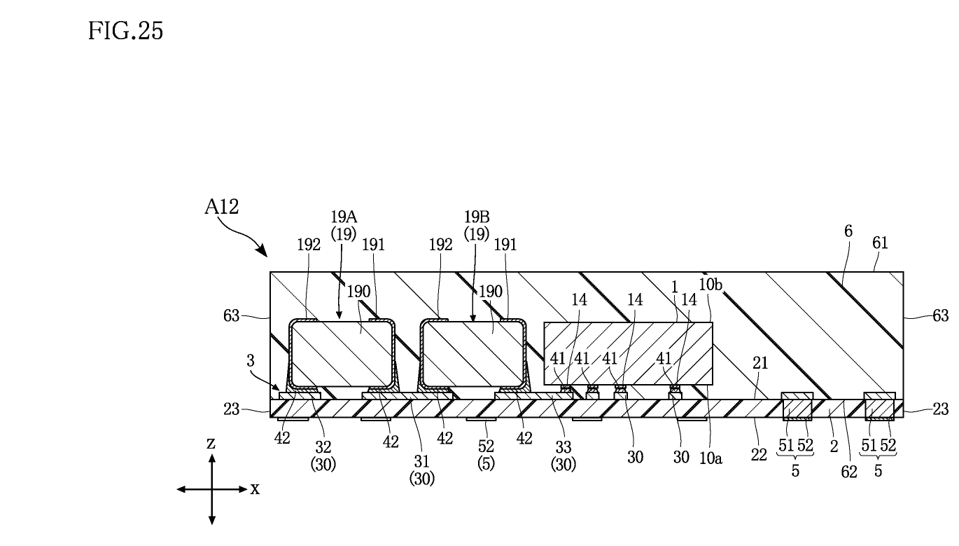

FIG. 25 shows an electronic device A12 according to a second variation of the first embodiment. The electronic device A12 is different from the electronic device A10 in that the thickness (the dimension in the thickness direction z) of the semiconductor element 1 in the electronic device A12 is greater than the thickness of the semiconductor element 1 in the electronic device A10.

As in the electronic device A10, the height of each electronic component 19 in the electronic device A12 is reduced. If there is a difference between the thickness (the dimension in the thickness direction z) of each electronic component 19 and the thickness (the dimension in the thickness direction z) of the semiconductor element 1 even after the height of each electronic component 19 is reduced, the thickness of the semiconductor element 1 may be increased to be approximately the same as the thickness of each electronic component 19. Increasing the volume of the semiconductor element 1 as described above can reduce the volume (amount) of the sealing resin 6. Since the volume (amount) of the sealing resin 6 is reduced, the stress applied by the sealing resin 6 to the support member 2 can be suppressed. Thus, in the electronic device A12, the warpage of the support member 2 can be reduced as compared to that in the electronic device A10.

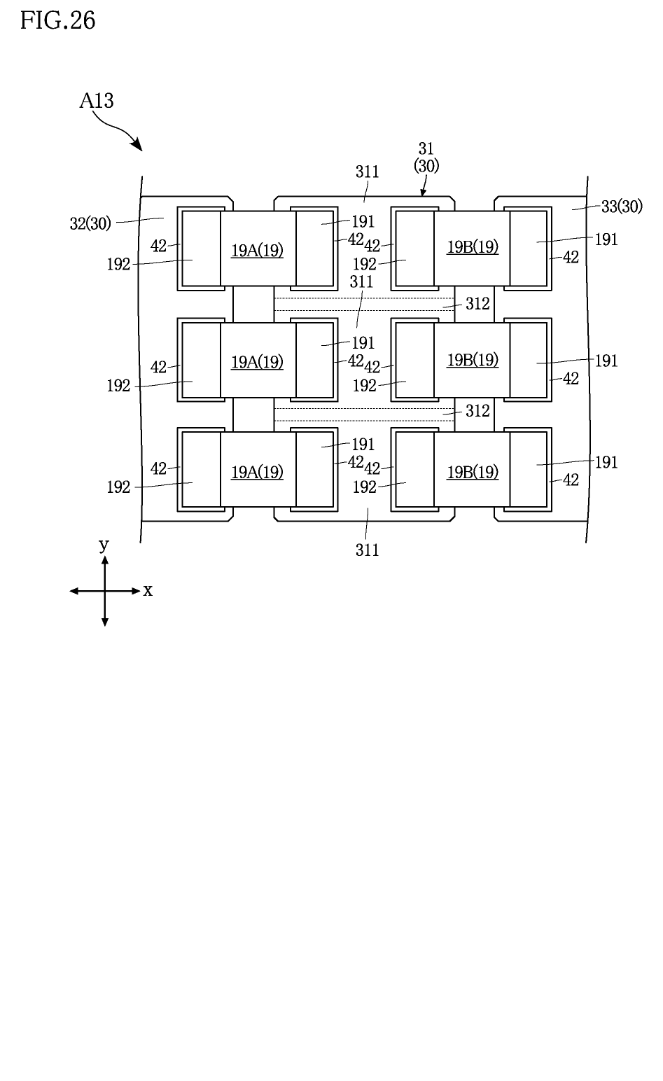

FIG. 26 shows an electronic device A13 according to a third variation of the first embodiment. The electronic device A13 is different from the electronic device A10 in the following points. First, the electronic components 19 include three first electronic components 19A. Second, the electronic components 19 include three second electronic components 19B.

In the electronic device A13, the three first electronic components 19A are electrically connected to each other in parallel, and the three second electronic components 19B are electrically connected to each other in parallel. The three first electronic components 19A are electrically connected to the three second electronic components 19B in series. Thus, in the electronic device of the present disclosure, the number of first electronic components 19A and the number of second electronic components 19B are not particularly limited. Although the number of first electronic components 19A and the number of second electronic components 19B are the same in each of the electronic devices A10 and A13, these numbers may be different from each other.

As with the electronic device A10, each of the electronic devices A11 to A13 includes a first wiring section 31 to which either the terminal 191 or 192 of each of a plurality of electronic components (at least one first electronic component 19A and at least one second electronic component 19B) is bonded, and the electrical characteristics of the electronic components 19 are equivalently represented by a single circuit symbol in a circuit diagram. Thus, as with the electronic device A10, each of the electronic devices A11 to A13 can be designed to have highly accurate electrical specifications and reduced thickness, thereby improving flexibility in module design. Further, each of the electronic devices A11 to A13 has advantages similar to the electronic device A10 owing to its configuration common with the electronic device A10.

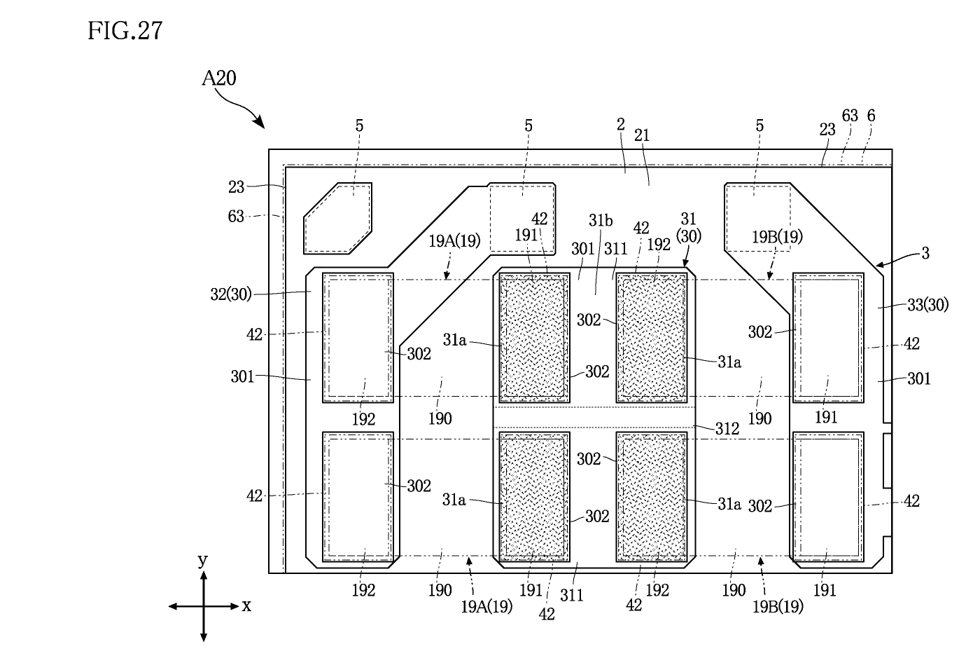

FIGS. 27 to 29 show an electronic device A20 according to a second embodiment. The electronic device A20 is different from the electronic device A10 in that each of the first wiring section 31, the second wiring section 32, and the third wiring section 33 includes a body 301 and a plurality of bases 302.

The body 301 includes a seed layer (that contains titanium (Ti), for example) and a metal layer (that contains Cu, for example). The bases 302 are stacked on the body 301. Each of the bases 302 is disposed at a portion to which an electronic component 19 is bonded, and is located between the body 301 and a corresponding conductive bonding member 42. Each of the bases 302 contains the same metal (e.g., Cu) as the metal layer of the body 301. Unlike this example, each of the bases 302 may contain a different metal (e.g., nickel) from the metal layer of the body 301. For example, when each of the bases 302 contains nickel, the base 302 functions as a barrier metal and prevents the conductive bonding member 42 from penetrating into the wiring layer 3 (the metal layer of the body 301).

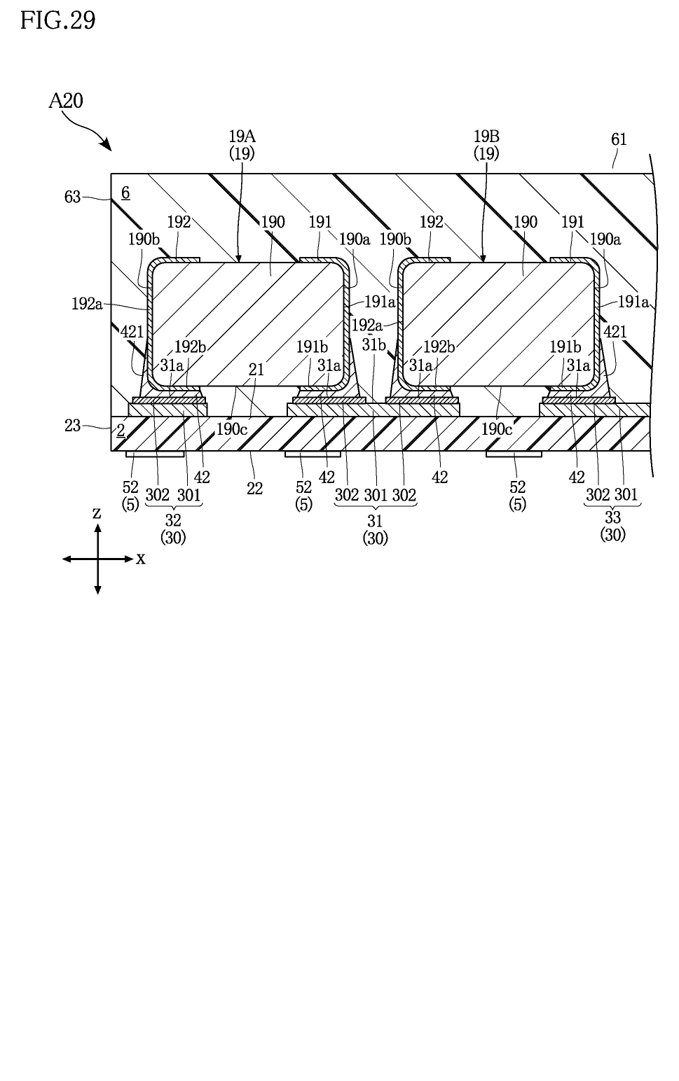

As shown in FIGS. 27 and 29, the first wiring section 31 in the electronic device A20 includes a plurality of bonding surfaces 31a and a recess 31b. In FIG. 27, the bonding surfaces 31a are indicated with dots. Each of the bonding surfaces 31a is a surface of the first wiring section 31 that is in contact with a corresponding conductive bonding member 42. In the present embodiment, four conductive bonding members 42 are arranged on the first wiring section 31, and thus the first wiring section 31 includes four bonding surfaces 31a. Each of the bonding surfaces 31a corresponds to the upper surface of one of the bases 302 in the first wiring section 31. The recess 31b is a portion recessed from the bonding surfaces 31a to the support surface 21 of the support member 2 in the thickness direction z. In the present embodiment, the recess 31b is located between adjacent ones of the bonding surfaces 31a in plan view. In the illustrated example, the recess 31b includes a linear portion extending in the first direction x in plan view, and a linear portion extending in the second direction y in plan view, and these portions intersect at the center of the first wiring section 31. In the electronic device A20, the first wiring section 31 includes the body 301 and the bases 302. Thus, as shown in FIG. 29, the portions of the first wiring section 31 to which the electronic components 19 are bonded (the portions in contact with the conductive bonding members 42) are partially elevated. As a result, the recess 31b is formed in the first wiring section 31. Although details are omitted, in the example shown in FIG. 27, each of the second wiring section 32 and the third wiring section 33 includes a body 301 and a plurality of bases 302. Thus, each of the second wiring section 32 and the third wiring section 33 includes a plurality of bonding surfaces and a recess similar to the bonding surfaces 31a and the recess 31b of the first wiring section 31.

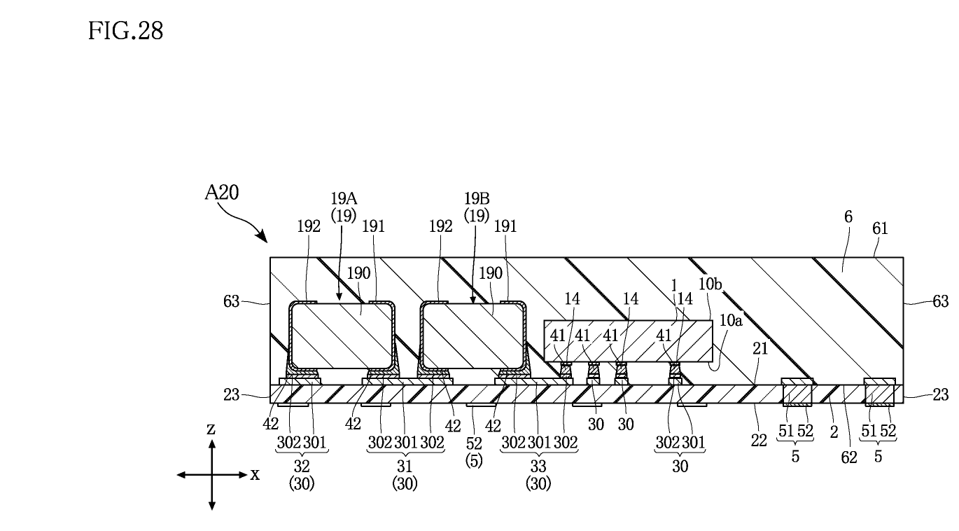

As shown in FIG. 28, the electronic device A20 further includes a base 302 formed in the bonding area of the semiconductor element 1. Unlike this example, the base 302 may not be formed in the bonding area of the semiconductor element 1. Further, bases 302 only need to be formed at least in the bonding areas of the two first electronic components 19A and the two second electronic components 19B, and may not be formed in the bonding areas of other electronic components 19.

As with the electronic device A10, the electronic device A20 includes the first wiring section 31 to which either the terminal 191 or 192 of each of a plurality of electronic components (at least one first electronic component 19A and at least one second electronic component 19B) is bonded, and the electrical characteristics of the electronic components 19 are equivalently represented by a single circuit symbol in a circuit diagram. Thus, as with the electronic device A10, the electronic device A20 can be designed to have highly accurate electrical specifications and reduced thickness, thereby improving flexibility in module design. Further, the electronic device A20 has advantages similar to the electronic device A10 owing to its configuration common with the electronic device A10.

In the electronic device A20, the recess 31b is provided between the bonding surfaces 31a. With this configuration, there is a step between each bonding surface 31a and the recess 31b. The step can suppress the wetting and spreading of the conductive bonding members 42 along the wiring layer 3. This suppresses the outflow of the conductive bonding members 42, thereby preventing insufficient thickness of the conductive bonding members 42 and tilting of the electronic components 19. In other words, the electronic device A20 can suppress bonding failures of the electronic components 19 and prevent a decrease in reliability.

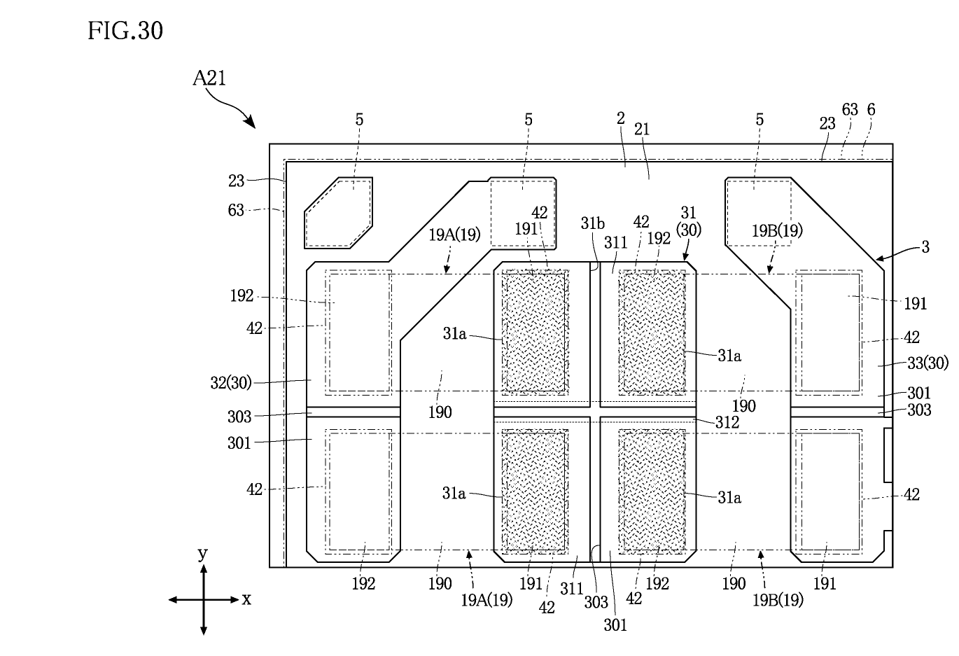

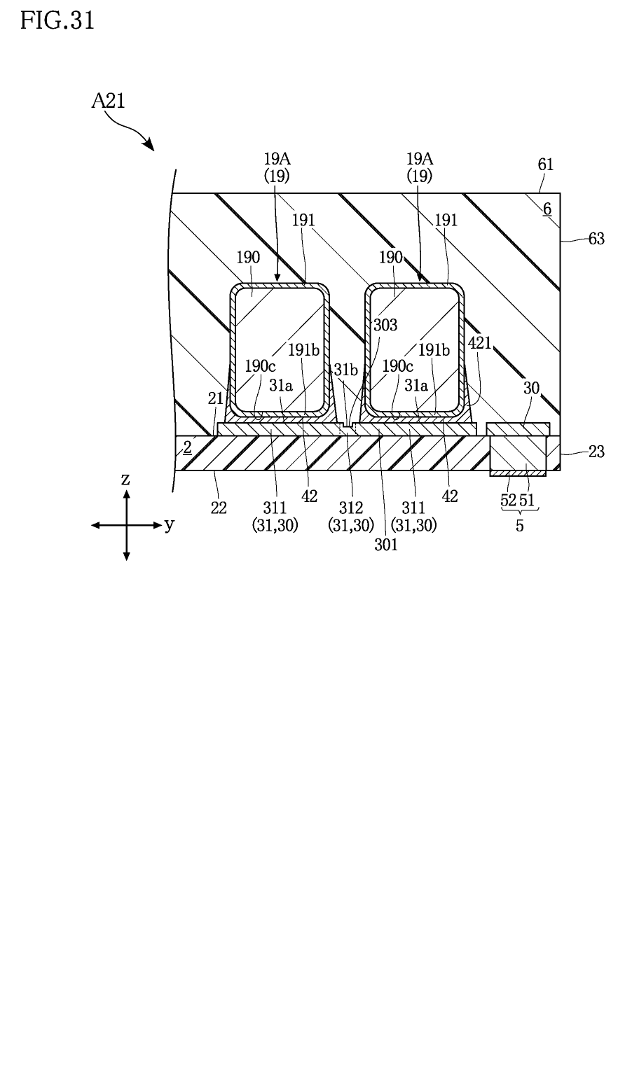

FIGS. 30 and 31 show an electronic device A21 according to a first variation of the second embodiment. The electronic device A21 is different from the electronic device A20 in that each of the first wiring section 31, the second wiring section 32, and the third wiring section 33 includes a body 301 and a groove 303.

As shown in FIG. 31, the groove 303 of the first wiring section 31 is recessed downward in the thickness direction z (toward the support surface 21 in the thickness direction z) from the body 301. This is also the case in the second wiring section 32 and the third wiring section 33. In the electronic device A21, each of the first wiring section 31, the second wiring section 32, and the third wiring section 33 includes a groove 303. As a result, in each of the first wiring section 31, the second wiring section 32, and the third wiring section 33, a recess is formed between portions to which each electronic component 19 is bonded. In the illustrated example, each of the grooves 303 extends in the first direction x or the second direction y in plan view. Unlike this configuration, a plurality of grooves 303 may be arranged intermittently in the first direction x or the second direction y.

As shown in FIGS. 30 and 31, the first wiring section 31 in electronic device A21 includes a plurality of bonding surfaces 31a and a recess 31b. In FIG. 30, the bonding surfaces 31a are indicated with dots. The recess 31b is located between adjacent ones of the bonding surfaces 31a in plan view. In the illustrated example, the recess 31b includes a linear portion extending in the first direction x in plan view, and a linear portion extending in the second direction y in plan view, and these portions intersect at the center of the first wiring section 31. The linear portion of the recess 31b that extends in the first direction x is formed in the connecting area 312. In the electronic device A21, the first wiring section 31 includes the body 301 and the groove 303. Thus, as shown in FIG. 31, a part of the first wiring section 31 is recessed between the portions of the first wiring section 31 to which the electronic components 19 are bonded (the portions in contact with the conductive bonding members 42). As a result, the recess 31b is formed in the first wiring section 31. That is, in the electronic device A21, the recess 31b corresponds to the groove 303. Unlike this configuration, a plurality of grooves 303 may extend intermittently in plan view. In this case, the first wiring section 31 includes a plurality of recesses 31b each arranged in the first direction x or the second direction y. Although details are omitted, in the example shown in FIG. 30, each of the second wiring section 32 and the third wiring section 33 includes a body 301 and a groove 303. Thus, each of the second wiring section 32 and the third wiring section 33 includes a plurality of bonding surfaces and a recess similar to the bonding surfaces 31a and the recess 31b of the first wiring section 31.

As with the electronic device A20, the electronic device A21 includes the first wiring section 31 to which either the terminal 191 or 192 of each of a plurality of electronic components (at least one first electronic component 19A and at least one second electronic component 19B) is bonded, and the electrical characteristics of the electronic components 19 are equivalently represented by a single circuit symbol in a circuit diagram. As in the electronic device A20, the electronic components 19 in the electronic device A21 are two first electronic components 19A and two second electronic components 19B. Thus, as with the electronic device A20, the electronic device A21 can be designed to have highly accurate electrical specifications and reduced thickness, thereby improving flexibility in module design. Further, the electronic device A21 has advantages similar to the electronic device A20 owing to its configuration common with the electronic device A20.

In the electronic device A21, as in the electronic device A20, the recess 31b is provided between the bonding surfaces 31a. Thus, similarly to the electronic device A20, the electronic device A21 can also prevent tilting of the electronic components 19. Unlike the electronic device A20, the electronic device A21 includes a groove 303 in the body 301 of each of the first wiring section 31, the second wiring section 32, and the third wiring section 33, whereby bonding surfaces 31a and a recess 31b are provided for each of these wiring sections.

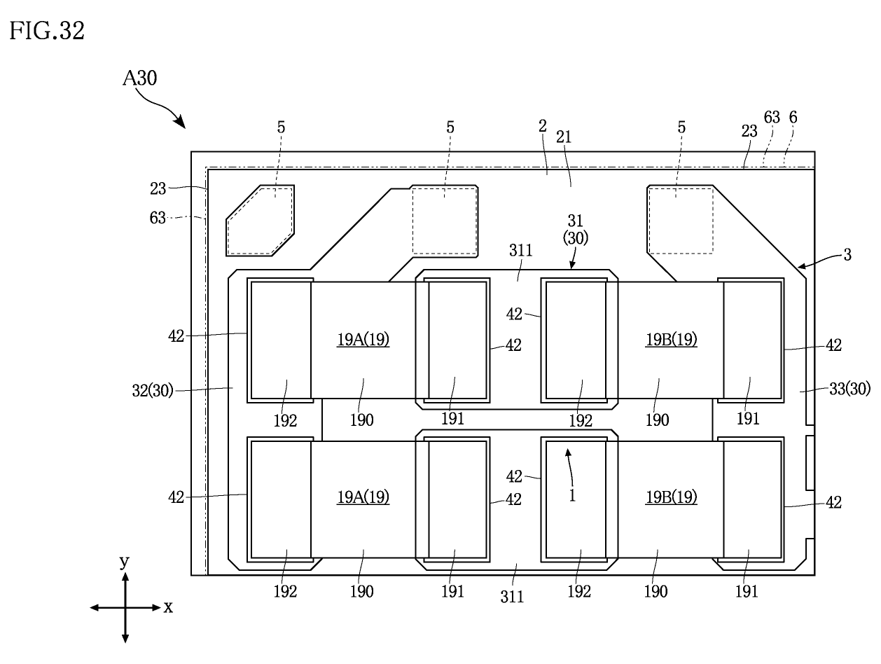

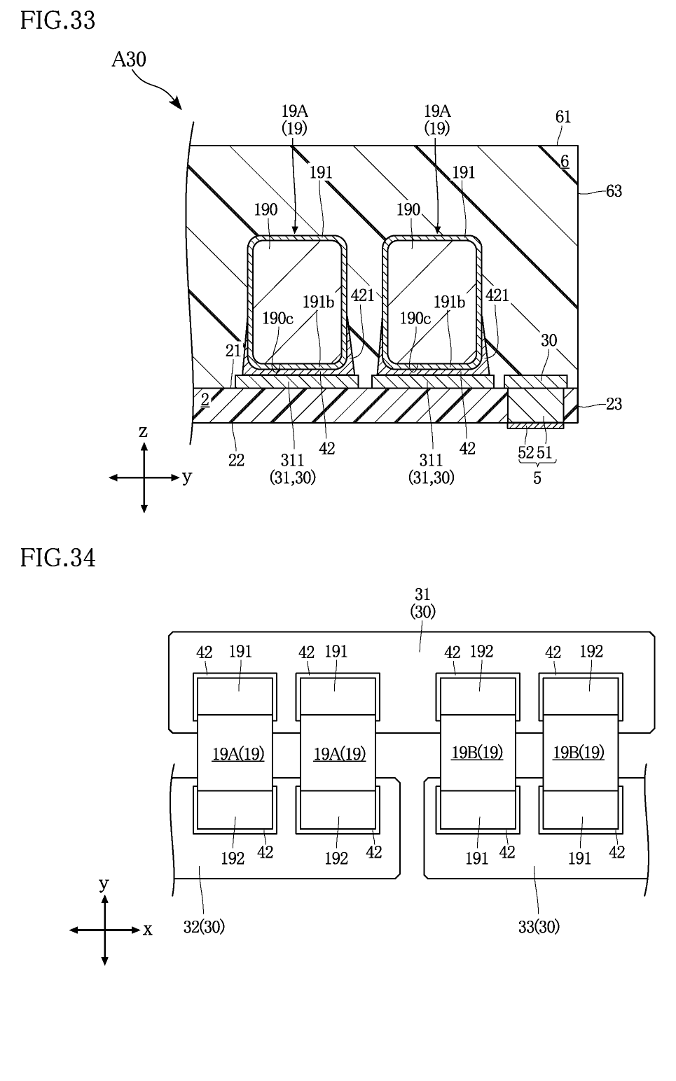

FIGS. 32 and 33 show an electronic device A30 according to a third embodiment. The electronic device A30 is different from the electronic device A10 in that the first wiring section 31 includes two partitioned areas 311 spaced apart from each other.

As shown in FIGS. 32 and 33, the first wiring section 31 does not include the connecting area 312. As a result, the two partitioned areas 311 are separated from each other. In this configuration, one of the two first electronic components 19A and one of the two second electronic components 19B are electrically connected to each other in series via one of the two partitioned areas 311. Further, the other of the two first electronic components 19A and the other of the two second electronic components 19B are electrically connected to each other in series via the other of the two partitioned areas 311. Then, series circuits each including a single first electronic component 19A and a single second electronic component 19B are electrically connected to each other in parallel.

As with the electronic device A10, the electronic device A30 includes the first wiring section 31 to which either the terminal 191 or 192 of each of a plurality of electronic components (at least one first electronic component 19A and at least one second electronic component 19B) is bonded, and the electrical characteristics of the electronic components 19 are equivalently represented by a single circuit symbol in a circuit diagram. Thus, as with the electronic device A10, the electronic device A30 can be designed to have highly accurate electrical specifications and reduced thickness, thereby improving flexibility in module design. Further, the electronic device A30 has advantages similar to the electronic device A10 owing to its configuration common with the electronic device A10.

In each of the electronic devices A10 to A13, A20, A21, and A30 according to the first to third embodiments (including the variations thereof), the first wiring section 31, the second wiring section 32, and the third wiring section 33 may not be arranged in a direction (e.g., the first direction x) perpendicular to the thickness direction z. FIG. 34 shows an arrangement example of the first wiring section 31, the second wiring section 32, and the third wiring section 33 according to such a variation.

In the electronic device shown in FIG. 34, the first wiring section 31 is offset to a first side in the second direction y relative to the second wiring section 32 and the third wiring section 33. The second wiring section 32 and the third wiring section 33 are aligned in the first direction x. In this configuration as well, the two first electronic components 19A are disposed with their longer sides extending in the second direction y, and are bonded to the first wiring section 31 and the second wiring section 32. The two second electronic components 19B are disposed with their longer sides extending in the second direction y, and are bonded to the first wiring section 31 and the third wiring section 33. In the illustrated example, the two first electronic components 19A and the two second electronic components 19B are disposed in the first direction x. In the example shown in FIG. 34, the two first electronic components 19A and the two second electronic components 19B are aligned without deviation in the first direction x. However, the two first electronic components 19A and the two second electronic components 19B may be deviated as long as their electrical connections remain the same. For example, misalignment of the two first electronic components 19A and the two second electronic components 19B may occur as a result of manufacturing errors.

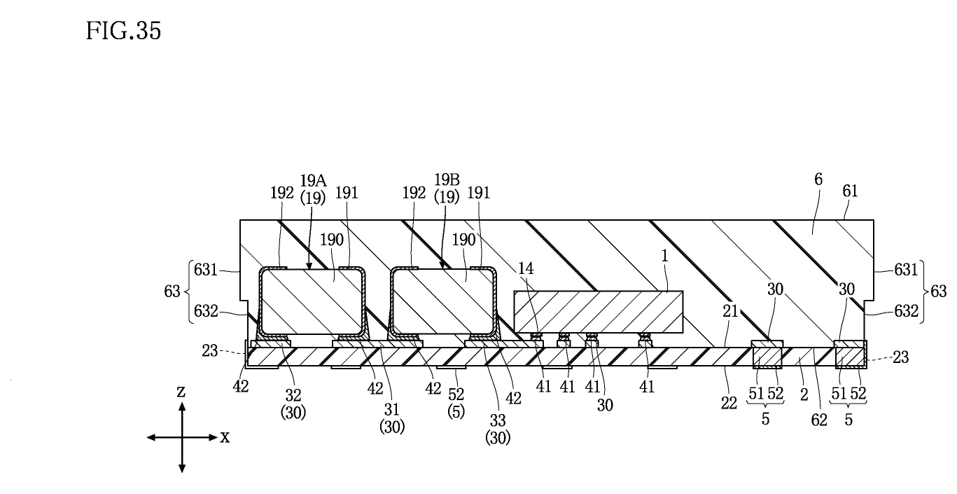

In each of the electronic devices A10 to A13, A20, A21, and A30 according to the first to third embodiments (including the variations thereof), Each resin side surface 63 of the sealing resin 6 may have a step. FIG. 35 shows an electronic device according to such a variation, where the variation is applied to the electronic device A10 according to the first embodiment. Although FIG. 35 shows an example where the variation is applied to the electronic device A10 according to the first embodiment, the variation can instead be applied to the electronic devices according to the other embodiments.

In the electronic device shown in FIG. 35, each of the resin side surfaces 63 has a first side portion 631 and a second side portion 632. In each of the resin side surfaces 63, the first side portion 631 and the second side portion 632 face in the same direction. The first side portion 631 is located outward relative to the second side portion 632 in plan view. The first side portion 631 is connected to the resin obverse surface 61, and the second side portion 632 is connected to a corresponding one of the side surfaces 23. The second side portion 632 is flush with the corresponding side surface 23. With this configuration, each of the resin side surfaces 63 has a step. In the electronic device shown in FIG. 35, the outer terminals 5 include one whose columnar portion 51 is exposed from a side surface 23. In the outer terminal 5 whose columnar portion 51 is exposed from a side surface 23, the external electrode portion 52 covers the surface of the columnar portion 51 that is exposed from the reverse surface 22 of the support member 2 and the surface of the columnar portion 51 that is exposed from the side surface 23 of the support member 2.

The electronic device shown in FIG. 35 also has the same advantages as the electronic device A10. In addition, the electronic device shown in FIG. 35 includes an outer terminal 5 whose external electrode portion 52 is also formed on the surface of the columnar portion 51 exposed from a side surface 23. With this configuration, when the electronic device shown in FIG. 35 is mounted onto the wiring board of an electronic apparatus or the like, a fillet can be formed in a conductive bonding material (e.g., solder) used for the mounting. Thus, the electronic device shown in FIG. 35 facilitates visual inspection to determine whether the electronic device is appropriately bonded to the wiring board of an electronic apparatus or the like.

In the first to third embodiments (including these variations), the second wiring section 32 and the third wiring section 33 are electrically connected to each other via a plurality of electronic components (at least one first electronic component 19A and at least one second electronic component 19B) and the first wiring section 31. In the electronic device of the present disclosure, however, two wiring sections 30 may be electrically connected to each other only via a plurality of electronic components 19. Even in this configuration, the electronic components 19 are electrically connected such that the electrical characteristics of the electronic components 19 are equivalently represented by a circuit symbol in a circuit diagram. For example, in the layout shown in FIG. 2, two electronic components 19, which are disposed on an area of the support member 2 located on the first side in the first direction x and at the center in the second direction y, are bonded to two wiring sections 30. The two wiring sections 30 are electrically connected to each other via the two electronic components 19.

In the electronic device of the present disclosure, the number and arrangement of semiconductor elements 1 and electronic components 19, the pattern of the wiring layer 3 (the number and arrangement of wiring sections 30), and the number and arrangement of outer terminals 5 are not limited to the illustrated examples. In other words, the planar layout of the electronic device according to the present disclosure may take various forms according to the specifications of the electronic device.

The electronic device of the present disclosure is not limited to the configuration with the semiconductor element 1 as a functional element, as long as the electronic device includes a plurality of electronic component 19.

The electronic device according to the present disclosure is not limited to the above embodiments. Various design changes can be made to the specific configurations of the elements of the electronic device according to the present disclosure. For example, the present disclosure includes the embodiments described in the following clauses.

Clause 1.

An electronic device comprising: a plurality of electronic components, each including a pair of terminals; a support member including a support surface that supports the plurality of electronic components; a wiring layer formed on the support surface; and a sealing resin covering each of the plurality of electronic components, wherein the wiring layer includes a first wiring section to which one of the pair of terminals of each of the plurality of electronic components is bonded, and electrical characteristics of the plurality of electronic components are equivalently represented by a single circuit symbol in a circuit diagram.

Clause 2.

The electronic device according to clause 1, wherein the wiring layer includes a second wiring section and a third wiring section that are spaced apart from the first wiring section and from each other, each of the plurality of electronic components is electrically connected between the second wiring section and the third wiring section, and the plurality of electronic components include at least one first electronic component having a pair of terminals bonded to the first wiring section and the second wiring section, and at least one second electronic component having a pair of terminals bonded to the first wiring section and the third wiring section.

Clause 3.

The electronic device according to clause 2, wherein the at least one first electronic component includes two first electronic components, the at least one second electronic component includes two second electronic components, and the two first electronic components are electrically connected to the two second electronic components in series.

Clause 4.

The electronic device according to clause 3, wherein each of the plurality of electronic components includes a body, the support surface faces a first side in a thickness direction of the support member, and the pair of terminals of each of the plurality of electronic components are formed on respective ends of the body in a first direction perpendicular to the thickness direction.

Clause 5.

The electronic device according to clause 4, wherein the first wiring section, the second wiring section, and the third wiring section are disposed in the first direction, and the first wiring section is located between the second wiring section and the third wiring section.

Clause 6.

The electronic device according to clause 5, wherein the first wiring section includes two partitioned areas that are spaced apart from each other, one of the two first electronic components and one of the two second electronic components are bonded to one of the two partitioned areas, and the other of the two first electronic components and the other of the two second electronic components are bonded to the other of the two partitioned areas.

Clause 7.

The electronic device according to clause 6, wherein the first wiring section includes a connecting area that is located between the two partitioned areas, and that connects the two partitioned areas.

Clause 8.

The electronic device according to any of clauses 5 to 7, wherein the two first electronic components overlap with each other as viewed in a second direction perpendicular to the thickness direction and the first direction, the two second electronic components overlap with each other as viewed in the second direction, and as viewed in the first direction, the two first electronic components overlap with the two second electronic components, respectively.

Clause 9.

The electronic device according to any of clauses 1 to 8, further comprising a plurality of outer terminals, wherein the support member includes a reverse surface facing away from the support surface in the thickness direction of the support member, the plurality of outer terminals are exposed from the reverse surface, and the first wiring section is electrically connected to the plurality of outer terminals via the plurality of electronic components.

Clause 10.

The electronic device according to any of clauses 1 to 9, further comprising a plurality of conductive bonding members, wherein each of the plurality of conductive bonding members bonds the first wiring section and one of the pair of terminals of each of the plurality of electronic components.

Clause 11.

The electronic device according to clause 10, wherein the first wiring section includes a plurality of bonding surfaces in contact with the respective conductive bonding members, and at least one recess recessed from the plurality of bonding surfaces to the support surface in the thickness direction of the support member, and as viewed in the thickness direction, the at least one recess is located between adjacent ones of the plurality of bonding surfaces.

Clause 12.

The electronic device according to any of clauses 1 to 11, wherein each of the plurality of electronic components exhibits a same performance with respect to the electrical characteristic.

Clause 13.

The electronic device according to clause 12, wherein the electrical characteristic is one of a capacitance, a resistance value, or an inductance value.

Clause 14.

The electronic device according to any of clauses 1 to 13, further comprising a semiconductor element, wherein the semiconductor element is flip-chip mounted on the wiring layer.

Clause 15.

The electronic device according to clause 14, wherein as viewed in the thickness direction of the support member, the plurality of electronic components are arranged around the semiconductor element.

Clause 16.

The electronic device according to clause 14 or 15, wherein the sealing resin covers the semiconductor element together with the plurality of electronic components.

Clause 17.

The electronic device according to any of clauses 1 to 16, wherein the support member contains an insulating resin material.

Clause 18.

The electronic device according to clause 17, wherein the support member contains a same resin material as the sealing resin.

### REFERENCE NUMERALS

A10, A11, A12, A13, A20, A21, A30: Electronic device

1: Semiconductor element 10a: Element obverse surface

10b: Element reverse surface 14: Electrode pad

19: Electronic component 19A: First electronic component

19B: Second electronic component 19C, 19D, 19X: Electronic component

190: Body 190a, 190b: Side surface

190c: Bottom surface 191, 192: Terminal

191a, 192a: Side electrode 191b, 192b: Bottom electrode

2: Support member 21: Support surface

22: Reverse surface 23: Side surface

3: Wiring layer 30: Wiring section

301: Body 302: Base

303: Groove 31: First wiring section

31a: Bonding surface 31b: Recess

311: Partitioned area 312: Connecting area

32: Second wiring section 33: Third wiring section

34, 35, 36: Wiring section 41, 42: Conductive bonding member

421: Fillet portion 5: Outer terminal

51: Columnar portion 52: External electrode portion

6: Sealing resin 61: Resin obverse surface

62: Resin reverse surface 63: Resin side surface

631: First side portion 632: Second side portion

80: Support substrate 80a: Substrate obverse surface

80b: Substrate reverse surface 82: First resin layer

86: Second resin layer 410, 420: Conductive bonding member

821: Obverse surface 822: Bottom surface

851: Columnar conductor 861: Top surface

CL: Cut line

1. An electronic device comprising:
a plurality of electronic components, each including a pair of terminals;
a support member including a support surface that supports the plurality of electronic components;
a wiring layer formed on the support surface; and
a sealing resin covering each of the plurality of electronic components,
wherein the wiring layer includes a first wiring section to which one of the pair of terminals of each of the plurality of electronic components is bonded, and
electrical characteristics of the plurality of electronic components are equivalently represented by a single circuit symbol in a circuit diagram.

2. The electronic device according to claim 1, wherein the wiring layer includes a second wiring section and a third wiring section that are spaced apart from the first wiring section and from each other,
each of the plurality of electronic components is electrically connected between the second wiring section and the third wiring section, and
the plurality of electronic components include at least one first electronic component having a pair of terminals bonded to the first wiring section and the second wiring section, and at least one second electronic component having a pair of terminals bonded to the first wiring section and the third wiring section.

3. The electronic device according to claim 2, wherein the at least one first electronic component includes two first electronic components,
the at least one second electronic component includes two second electronic components, and
the two first electronic components are electrically connected to the two second electronic components in series.

4. The electronic device according to claim 3, wherein each of the plurality of electronic components includes a body,
the support surface faces a first side in a thickness direction of the support member, and
the pair of terminals of each of the plurality of electronic components are formed on respective ends of the body in a first direction perpendicular to the thickness direction.

5. The electronic device according to claim 4, wherein the first wiring section, the second wiring section, and the third wiring section are disposed in the first direction, and
the first wiring section is located between the second wiring section and the third wiring section.

6. The electronic device according to claim 5, wherein the first wiring section includes two partitioned areas that are spaced apart from each other,
one of the two first electronic components and one of the two second electronic components are bonded to one of the two partitioned areas, and
the other of the two first electronic components and the other of the two second electronic components are bonded to the other of the two partitioned areas.

7. The electronic device according to claim 6, wherein the first wiring section includes a connecting area that is located between the two partitioned areas, and that connects the two partitioned areas.

8. The electronic device according to claim 5, wherein the two first electronic components overlap with each other as viewed in a second direction perpendicular to the thickness direction and the first direction,
the two second electronic components overlap with each other as viewed in the second direction, and
as viewed in the first direction, the two first electronic components overlap with the two second electronic components, respectively.

9. The electronic device according to claim 1, further comprising a plurality of outer terminals,
wherein the support member includes a reverse surface facing away from the support surface in the thickness direction of the support member,
the plurality of outer terminals are exposed from the reverse surface, and
the first wiring section is electrically connected to the plurality of outer terminals via the plurality of electronic components.

10. The electronic device according to claim 1, further comprising a plurality of conductive bonding members,
wherein each of the plurality of conductive bonding members bonds the first wiring section and one of the pair of terminals of each of the plurality of electronic components.

11. The electronic device according to claim 10, wherein the first wiring section includes a plurality of bonding surfaces in contact with the respective conductive bonding members, and at least one recess recessed from the plurality of bonding surfaces to the support surface in the thickness direction of the support member, and
as viewed in the thickness direction, the at least one recess is located between adjacent ones of the plurality of bonding surfaces.

12. The electronic device according to claim 1, wherein each of the plurality of electronic components exhibits a same performance with respect to the electrical characteristic.

13. The electronic device according to claim 12, wherein the electrical characteristic is one of a capacitance, a resistance value, or an inductance value.

14. The electronic device according to claim 1, further comprising a semiconductor element,
wherein the semiconductor element is flip-chip mounted on the wiring layer.

15. The electronic device according to claim 14, wherein as viewed in the thickness direction of the support member, the plurality of electronic components are arranged around the semiconductor element.

16. The electronic device according to claim 14, wherein the sealing resin covers the semiconductor element together with the plurality of electronic components.

17. The electronic device according to claim 1, wherein the support member contains an insulating resin material.

18. The electronic device according to claim 17, wherein the support member contains a same resin material as the sealing resin.
